(19) United States
(12) Patent Application Publication
(10) Pub. No.: US 2025/0096138 A1
(43) Pub. Date: Mar. 20, 2025

(54) INTEGRATED CIRCUIT INCLUDING COMPLEMENTARY FIELD EFFECT TRANSISTOR

(71) Applicant: SAMSUNG ELECTRONICS CO., LTD., Suwon-si (KR)

(72) Inventors: Jaeha LEE, Suwon-si (KR); Sukjin KIM, Suwon-si (KR); Sangdo PARK, Suwon-si (KR); Yongho LEE, Suwon-si (KR); Hongmook CHOI, Suwon-si (KR)

(73) Assignee: SAMSUNG ELECTRONICS CO., LTD., Suwon-si (KR)

(21) Appl. No.: 18/739,664

(22) Filed: Jun. 11, 2024

(30) Foreign Application Priority Data
Sep. 19, 2023 (KR) 10-2023-0125007

(51) Int. Cl. H01L 23/528; H01L 27/092

(52) U.S. Cl. CPC H01L 23/5286; H10D 84/856

(57) ABSTRACT

Provided is an integrated circuit including a complementary field effect transistor including a first transistor and a second transistor arranged in a vertical direction on a front side of a substrate, a via structure extending in the vertical direction on the second transistor and interconnecting a source/drain of the second transistor to a source/drain of the first transistor, at least one frontside power rail disposed above the first transistor in the vertical direction and transmitting a first supply voltage to the first transistor, a backside via penetrating through the substrate in the vertical direction, and at least one backside power rail disposed on a back side of the substrate and transmitting a second supply voltage to the second transistor through the backside via, wherein the first supply voltage and the second supply voltage have different voltage levels, and the first transistor and the second transistor share a gate line.

### CROSS-REFERENCE TO RELATED APPLICATION

This application is based on and claims priority under 35 U.S.C. § 119 to Korean Patent Application No. 10-2023-0125007, filed on Sep. 19, 2023, in the Korean Intellectual Property Office, the disclosure of which is incorporated by reference herein in its entirety.

### BACKGROUND

### 1. Field

The disclosure relates to an integrated circuit, and more particularly, to an integrated circuit including a complementary field effect transistor and a method of designing the same.

### 2. Description of Related Art

Due to the need for high integration and advancements in semiconductor processes, the widths, spacing, and/or heights of wires included in an integrated circuit may decrease, and thus, the influence of parasitic elements of the wires may increase. Also, a power supply voltage of an integrated circuit may be reduced for reduced power consumption, high operating speed, etc., and thus, the influence of parasitic components of wires on the integrated circuit may become more significant. Therefore, there is an increased demand for a method of designing an integrated circuit that efficiently routes wires and vias.

### SUMMARY

The disclosure provides an integrated circuit for improving a power performance area (PPA) by implementing a complementary field effect transistor using a frontside power rail and a backside power rail and a method of designing the integrated circuit.

According to an aspect of the disclosure, an integrated circuit includes: a complementary field effect transistor including a first transistor and a second transistor arranged in a vertical direction on a front side of a substrate; a via structure extending in the vertical direction on the second transistor and connecting the second transistor to the first transistor; at least one frontside power rail above the first transistor in the vertical direction and configured to transmit a first supply voltage to the first transistor; a backside via penetrating through the substrate in the vertical direction; and at least one backside power rail on a back side of the substrate and configured to transmit a second supply voltage to the second transistor through the backside via, wherein the first supply voltage and the second supply voltage are different, and wherein the first transistor and the second transistor share a gate line.

According to an aspect of the disclosure, an integrated circuit includes: a first active region and a second active region arranged, in a vertical direction with respect to a substrate, on a front side of the substrate; a gate line extending in the vertical direction and connected to the first active region and the second active region; a via structure extending in the vertical direction on the second active region and connecting the first active region to the second active region; a frontside power rail above the first active region in the vertical direction and configured to transmit a first supply voltage to the first active region; a backside power rail on a back side of the substrate and configured to transmit a second supply voltage to a source/drain region of the second active region; and a direct backside contact extending in the vertical direction on the backside power rail and connecting the backside power rail to the source/drain region of the second active region, wherein the first supply voltage and the second supply voltage are different.

According to an aspect of the disclosure, an integrated circuit includes: a plurality of first active regions on a front side of a substrate, wherein each first active region of the plurality of first active regions extends in a first direction, is spaced apart from other first active regions of the plurality of first active regions in a second direction intersecting with the first direction, and has a first height in the second direction; a second active region overlapping the plurality of first active regions in a vertical direction with respect to the substrate and having a second height greater than the first height in the second direction; a gate line extending in the vertical direction and connected to the plurality of first active regions and the second active region; a plurality of via structures each extending in the vertical direction on the first active regions and connecting the plurality of first active regions to the second active region; at least one frontside power rail above the plurality of first active regions and the second active region in the vertical direction and configured to receive a first supply voltage; and at least one backside power rail on a back side of the substrate and configured to receive a second supply voltage, wherein the first supply voltage and the second supply voltage are different.

### BRIEF DESCRIPTION OF THE DRAWINGS

Embodiments of the disclosure will be more clearly understood from the following detailed description taken in conjunction with the accompanying drawings in which:

FIG. 1A is a schematic perspective view of an integrated circuit according to an embodiment;

FIG. 1B is a schematic perspective view of an integrated circuit according to an embodiment;

FIG. 2 is a schematic perspective view of an integrated circuit according to an embodiment;

FIG. 3 is a circuit diagram showing the integrated circuit of FIG. 2, according to an embodiment;

FIGS. 4A and 4B show layouts of the integrated circuit of FIG. 2, according to an embodiment;

FIG. 5A is a cross-sectional view taken along a line I-I′ of FIGS. 4A and 4B according to an embodiment;

FIG. 5B is a cross-sectional view taken along a line II-II′ of FIGS. 4A and 4B according to an embodiment;

FIG. 5C is a cross-sectional view taken along a line III-III′ of FIGS. 4A and 4B according to an embodiment;

FIG. 6 is a schematic perspective view of an integrated circuit according to an embodiment;

FIG. 7 is a cross-sectional view of the integrated circuit of FIG. 6, according to an embodiment;

FIG. 8 is a schematic perspective view of an integrated circuit according to an embodiment;

FIG. 9 is a cross-sectional view of the integrated circuit of FIG. 8, according to an embodiment;

FIG. 10A is a schematic perspective view of an integrated circuit according to an embodiment;

FIG. 10B is a schematic perspective view of an integrated circuit according to an embodiment;

FIG. 11 is a perspective view of an integrated circuit according to an embodiment;

FIGS. 12A and 12B show layouts of the integrated circuit of FIG. 11, according to an embodiment;

FIG. 13A is a schematic perspective view of an integrated circuit according to an embodiment;

FIG. 13B is a schematic perspective view of an integrated circuit according to an embodiment;

FIG. 14 is a perspective view of an integrated circuit according to an embodiment;

FIGS. 15A and 15B show layouts of the integrated circuit of FIG. 14, according to an embodiment;

FIG. 16 is a circuit diagram showing an integrated circuit according to an embodiment;

FIGS. 17A and 17B show layouts of the integrated circuit of FIG. 16, according to an embodiment;

FIGS. 18A and 18B show layouts of an integrated circuit according to an embodiment;

FIGS. 19A and 19B show layouts of an integrated circuit according to an embodiment;

FIGS. 20A and 20B show layouts of an integrated circuit according to an embodiment;

FIGS. 21A and 21B show layouts of an integrated circuit according to an embodiment;

FIGS. 22A, 22B, 22C, and 22D show devices according to one or more embodiments of the disclosure, respectively;

FIG. 23 is a flowchart of a method of manufacturing an integrated circuit, according to an embodiment;

FIG. 24 is a block diagram showing a system-on-chip (SoC) according to an embodiment; and

FIG. 25 is a block diagram showing a computing system including a memory storing a program, according to an embodiment.

### DETAILED DESCRIPTION

As used herein, the X-axis direction may be referred to as a first horizontal direction or a first direction, the Y-axis direction may be referred to as a second horizontal direction or a second direction, and the Z-axis direction may be referred to as a vertical direction. A plane including an X-axis and a Y-axis may be referred to as a horizontal plane, components placed in the +Z-axis direction relative to other components may be referred to as being above the other components, and components placed in the −Z-axis direction relative to other components may be referred to as being below the other components.

In the following description, like reference numerals refer to like elements throughout the specification. According to embodiments, a plurality of “unit”, “module”, “member”, and “block” may be implemented as a single component or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms first, second, third, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

An integrated circuit may be designed by arranging a plurality of standard cells. A standard cell is a unit of the layout of an integrated circuit and may be referred to as a “cell” according to embodiments. A standard cell may be designed to include a plurality of transistors to perform a pre-defined function. The standard cell method refers to a method of designing a dedicated large-scale integrated circuit custom-made according to the specification of a customer or a user by preparing standard cells having various functions and combining the standard cells. Standard cells are designed and verified in advance and registered to a standard cell library, and an integrated circuit may be designed by performing logical design, placement, and routing by combining standard cells by using computer aided design (CAD). When designing such an integrated circuit, the performance of the integrated circuit may be further improved by reducing the lengths of wires and/or vias and the routing complexity.

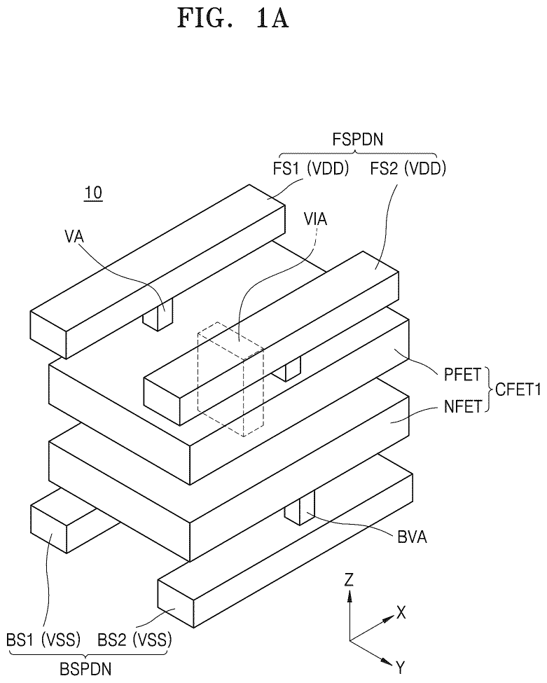

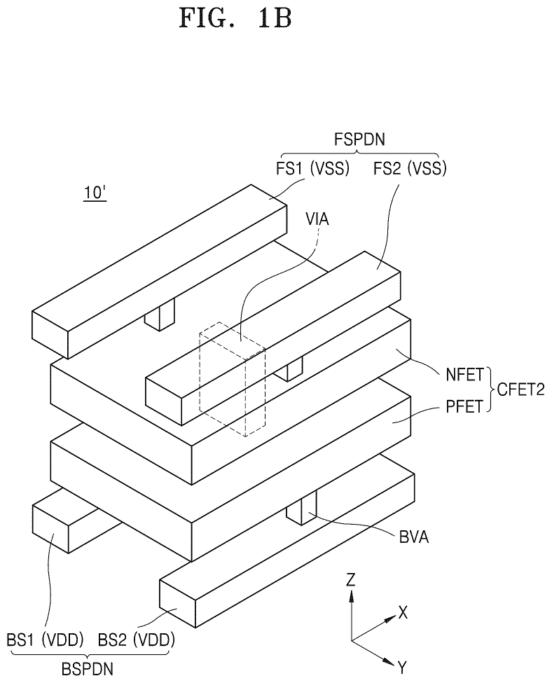

FIG. 1A is a schematic perspective view of an integrated circuit 10 according to an embodiment.

Referring to FIG. 1A, the integrated circuit 10 may include a complementary field effect transistor (CFET) CFET1. The CFET CFET1 may include a P-type FET (hereinafter referred to as PFET) and an N-type FET (hereinafter referred to as NFET) arranged in a vertical direction Z. According to an embodiment, the PFET may be disposed above the NFET in the vertical direction Z. The PFET and the NFET may be connected to each other through a via structure VIA extending in the vertical direction Z from the top of the NFET. According to an embodiment, the CFET CFET1 may be implemented as a standard cell.

The integrated circuit 10 may implement a power distribution network (PDN) by using frontside power rails FS1 and FS2 arranged on the front side of a substrate and backside power rails BS1 and BS2 arranged on the back side of the substrate. Here, the frontside power rails FS1 and FS2 may implement a frontside PDN FSPDN, and the backside power rails BS1 and BS2 may implement a backside PDN BSPDN. As such, by utilizing a dual PDN, the integrated circuit 10 may significantly reduce routing complexity as compared to a structure in which wires are arranged only on the front side of a substrate and may reduce lengths of wires or vias. Therefore, the performance of the integrated circuit 10 may be improved.

For example, the frontside power rails FS1 and FS2 may receive a positive supply voltage, e.g., a power voltage VDD, and the backside power rails BS1 and BS2 may receive a negative supply voltage, e.g., a ground voltage VSS. The backside power rails BS1 and BS2 may provide the ground voltage VSS to the NFET through backside vias BVA, and the frontside power rails FS1 and FS2 may provide the power voltage VDD to the PFET through frontside vias VA. Here, the number of frontside power rails FS1 and FS2 and the number of backside power rails BS1 and BS2 may vary according to embodiments.

FIG. 1B is a schematic perspective view of an integrated circuit 10′ according to an embodiment.

Referring to FIG. 1B, the integrated circuit 10′ corresponds to a modified example of the integrated circuit 10 of FIG. 1A, and descriptions given above with reference to FIG. 1A may be applied to the present embodiment. The integrated circuit 10′ may include a CFET CFET2. The CFET CFET2 may include an NFET and a PFET arranged in the vertical direction Z. According to an embodiment, the NFET may be disposed above the PFET in the vertical direction Z. The NFET and the PFET may be connected to each other through a via structure VIA extending in the vertical direction Z from the top of the PFET. According to an embodiment, the CFET CFET2 may be implemented as a standard cell.

For example, the frontside power rails FS1 and FS2 may receive a negative supply voltage, e.g., the ground voltage VSS, and the backside power rails BS1 and BS2 may receive a positive supply voltage, e.g., the power voltage VDD. The backside power rails BS1 and BS2 may provide the power voltage VDD to the PFET through the backside vias BVA, and the frontside power rails FS1 and FS2 may provide the ground voltage VSS to the NFET through the frontside vias VA.

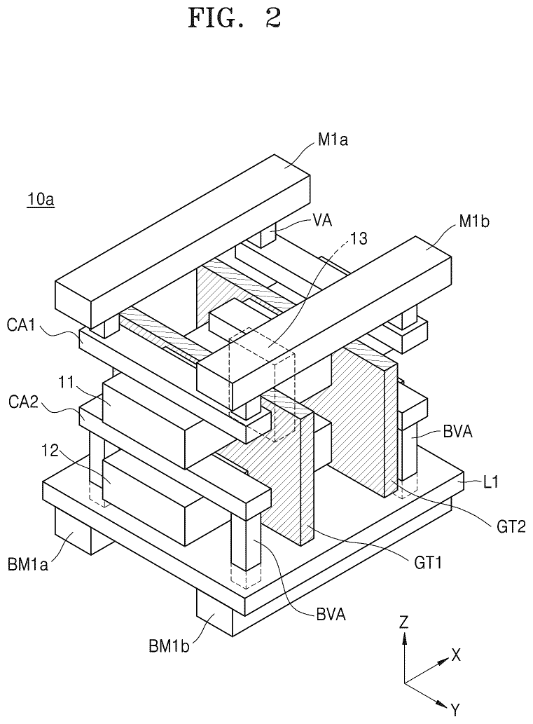

FIG. 2 is a schematic perspective view of an integrated circuit 10a according to an embodiment.

Referring to FIG. 2, the integrated circuit 10a corresponds to an implementation example of the integrated circuit 10 of FIG. 1A or the integrated circuit 10′ of FIG. 1B, and descriptions given above with reference to FIGS. 1A and 1B may be applied to the present embodiment. The integrated circuit 10a may include a first layer L1, a first active region 11, a second active region 12, gate lines GT1 and GT2, first contacts CA1, second contacts CA2, a via structure 13, the frontside vias VA, the backside vias BVA, frontside power rails M1a and M1b, and backside power rails BM1a and BM1b.

The second active region 12 may be disposed on the front side of the first layer L1, and the first active region 11 may be disposed above the second active region 12 in the vertical direction Z. Each of the gate lines GT1 and GT2 may extend in the vertical direction Z and be arranged to surround the first active region 11 and the second active region 12. Therefore, the first active region 11 and the second active region 12 may share the gate lines GT1 and GT2.

The first contacts CA1 may be arranged on the first active region 11 and may each extend in the second direction Y. The second contacts CA2 may be arranged on the second active region 12 and may each extend in the second direction Y. The via structure 13 extends in the vertical direction Z on the second active region 12, and thus the via structure 13 may electrically interconnect the second active region 12 to the first active region 11. For example, the via structure 13 may extend in the vertical direction Z and be electrically connected to the first contacts CA1 on the first active region 11.

The first active region 11, the gate lines GT1 and GT2, and the first contacts CA1 may implement an upper transistor or a first transistor, and the second active region 12, the gate lines GT1 and GT2, and the second contacts CA2 may implement a lower transistor or a second transistor. At this time, the first active region 11 and the second active region 12 may have different conductivity types, and the conductivity types of the first transistor and the second transistor may be different from each other. As such, the integrated circuit 10a may include a complementary field effect transistor including the first transistor and the second transistor. As used herein, and with regard to references to complementary field effect transistors, a transistor that is relatively far from a substrate will be referred to as an upper transistor or the first transistor, and a transistor that is relatively close to the substrate will be referred to as a lower transistor or the second transistor.

For example, the first active region 11, the gate lines GT1 and GT2, and the first contacts CA1 may correspond to the PFET of FIG. 1A, and the second active region 12, the gate lines GT1 and GT2, and the second contacts CA2 may correspond to the NFET of FIG. 1A. The integrated circuit 10a may correspond to the CFET CFET1 of FIG. 1A. According to an embodiment, the first active region 11, the gate lines GT1 and GT2, and the first contacts CA1 may correspond to the NFET of FIG. 1B, and the second active region 12, the gate lines GT1 and GT2, and the second contacts CA2 may correspond to the PFET of FIG. 1B. At this time, the integrated circuit 10a may correspond to the CFET CFET2 of FIG. 1B.

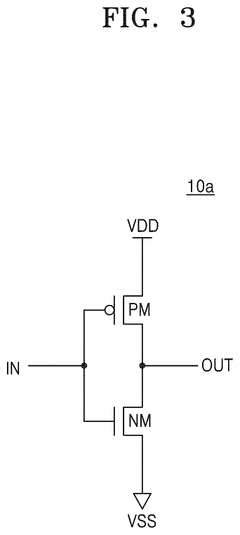

FIG. 3 is a circuit diagram showing the integrated circuit 10a of FIG. 2, according to an embodiment.

Referring to FIG. 3, the integrated circuit 10a may correspond to an inverter cell including a P-type transistor PM and an N-type transistor NM connected in series with each other. The P-type transistor PM may include a source that receives the power voltage VDD, a gate that receives an input signal IN, and a drain that provides an output signal OUT. The N-type transistor NM may include a source that receives the ground voltage VSS, a gate that receives the input signal IN, and a drain that provides the output signal OUT. For example, the P-type transistor PM may correspond to the PFET of FIG. 1A or 1B, and the N-type transistor NM may correspond to the NFET of FIG. 1A or 1B.

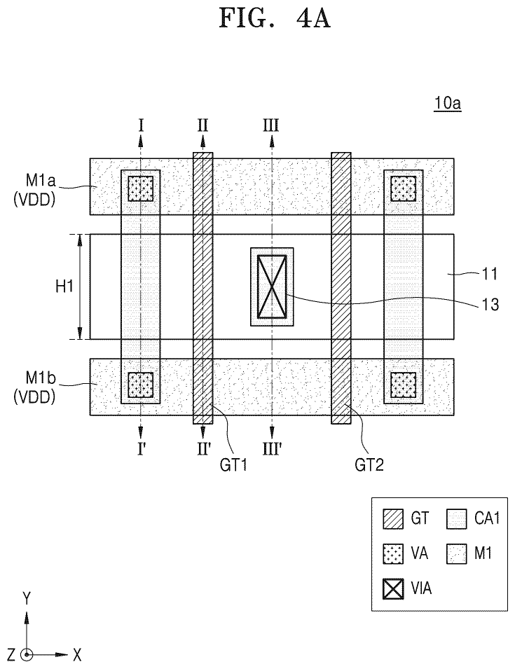

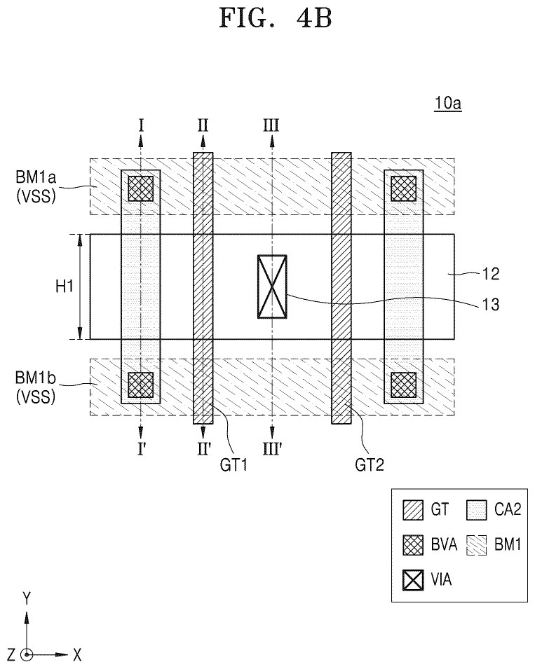

FIG. 4A shows a layout corresponding to the upper transistor of the integrated circuit 10a of FIG. 2, according to an embodiment.

Referring to FIG. 4A, the integrated circuit 10a may include the first active region 11, the gate lines GT1 and GT2, the first contacts CA1, the frontside vias VA, a frontside wiring layer M1, and the via structure 13. The first active region 11 may extend in the first direction X and have a first height H1 in the second direction Y. The first contacts CA1 may each extend in the second direction Y on the first active region 11 and be spaced apart from each other in the first direction X. At this time, the first contacts CA1 may correspond to source/drain contacts.

The gate lines GT1 and GT2 may each extend in the second direction Y and be spaced apart from each other in the first direction X. The frontside wiring layer M1 may include the frontside power rails M1a and M1b, each extending in the first direction X. For example, the frontside power rails M1a and M1b may receive the power voltage VDD, and the first active region 11, the first contacts CA1, and the gate lines GT1 and GT2 may constitute the P-type transistor PM of FIG. 3.

FIG. 4B shows a layout corresponding to the lower transistor of the integrated circuit 10a of FIG. 2, according to an embodiment.

Referring to FIG. 4B, the integrated circuit 10a may include the second active region 12, the gate lines GT1 and GT2, the second contacts CA2, a backside wiring layer BM1, the via structure 13, and the backside vias BVA. The second active region 12 may extend in the first direction X and have a first height H1 in the second direction Y. The second contacts CA2 may each extend in the second direction Y on the second active region 12 and be spaced apart from each other in the first direction X. At this time, the second contacts CA2 may correspond to source/drain contacts.

The gate lines GT1 and GT2 may each extend in the second direction Y and be spaced apart from each other in the first direction X. The backside wiring layer BM1 may include the backside power rails BM1a and BM1b, each extending in the first direction X. For example, the backside power rails BM1a and BM1b may receive the ground voltage VSS, and the second active region 12, the second contacts CA2, and the gate lines GT1 and GT2 may constitute the N-type transistor NM of FIG. 3.

The gate lines GT1 and GT2 may each extend in the vertical direction Z, and thus the upper transistor and the lower transistor of the integrated circuit 10a may share the gate lines GT1 and GT2. The via structure 13 may extend in the vertical direction Z, and thus the source/drain region of the first active region 11 may be electrically connected to the source/drain region of the second active region 12. In other words, in a CFET, the source/drain of the lower transistor may be connected to the source/drain of the upper transistor through the via structure 13.

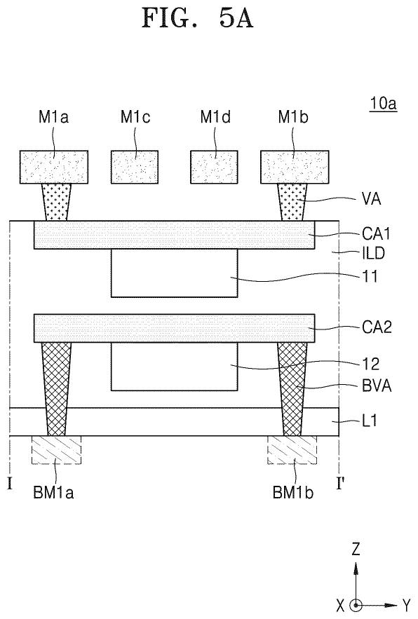

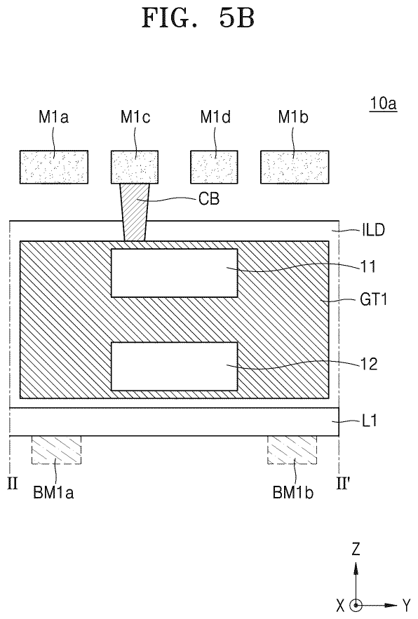

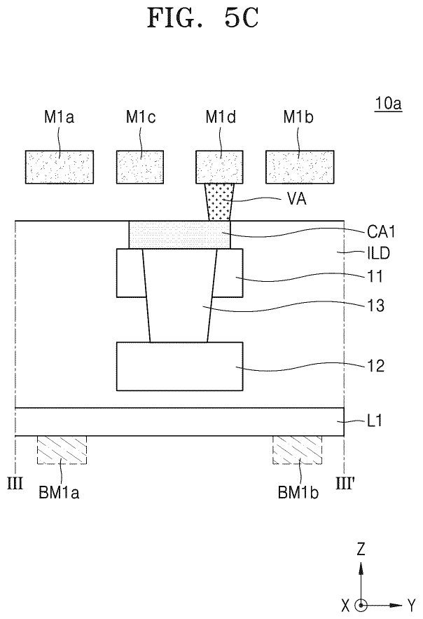

FIG. 5A is a cross-sectional view taken along a line I-I′ of FIGS. 4A and 4B according to an embodiment, FIG. 5B is a cross-sectional view taken along a line II-II′ of FIGS. 4A and 4B according to an embodiment, and FIG. 5C is a cross-sectional view taken along a line III-III′ of FIGS. 4A and 4B according to an embodiment.

Referring to FIGS. 5A to 5C together, the first layer L1 may include a substrate or a semiconductor substrate. For example, the semiconductor substrate may include any one of silicon, silicon-on-insulator, silicon-on-sapphire, germanium, silicon-germanium, and gallium-arsenide. An interlayer insulation layer ILD may be disposed on the first layer L1 in the vertical direction Z. The interlayer insulation layer ILD may include an insulation material. For example, the insulation material may include any one of an oxide layer, a nitride layer, and an oxynitride layer.

In one or more embodiments, the first layer L1 may correspond to a bulkless substrate. During the manufacturing process of the integrated circuit 10a, a device wafer may be formed by forming gate lines, source/drain regions, contacts, vias, and/or wiring layers on the front side of a substrate. Next, the device wafer may be temporarily bonded to a carrier wafer, and a back-grinding process may be performed on the device wafer to remove at least a portion of the substrate. In this way, a wafer that is back-grinded to reduce the height of the substrate to be equal to or below a standard height may be referred to as a “bulkless wafer” or a “bulkless substrate”.

The backside power rails BM1a and BM1b may be arranged to be spaced apart from each other in the second direction Y at the backside of the first layer L1. The backside vias BVA may be respectively arranged on the backside power rails BM1a and BM1b and each extend in the vertical direction Z to penetrate through the first layer L1. Therefore, the backside power rails BM1a and BM1b may be electrically connected to the second contacts CA2 through the backside vias BVA. According to embodiment, the height of a backside via BVA may be changed in various ways. For example, the height of the backside via BVA may be substantially similar to the height of the first layer L1, and additional vias and/or contacts may be arranged between the backside via BVA and the second contact CA2.

The frontside power rails M1a and M1b may be arranged above the first active region 11 and the first contact CA1 in the vertical direction Z on the front side of the first layer L1. The frontside vias VA may be arranged on the first contacts CA1 and may each extend in the vertical direction Z. Therefore, the frontside power rails M1a and M1b may be electrically connected to the first contacts CA1 through the frontside vias VA. According to an embodiment, the backside power rails BM1a and BM1b may be at least partially overlapped by the frontside power rails M1a and M1b in the vertical direction Z, respectively. For example, the backside power rails BM1a and BM1b may be aligned with respect to the frontside power rails M1a and M1b in the vertical direction Z.

According to the present embodiment, the second contacts CA2 may receive the ground voltage VSS from the two backside power rails BM1a and BM1b, respectively. Therefore, the second transistor of the second active region 12 may be implemented as a high-speed transistor that operates at high speed. Also, according to the present embodiment, the first contacts CA1 may receive the power voltage VDD from the two frontside power rails M1a and M1b, respectively. Therefore, the first transistor of the first active region 11 may be implemented as a high-speed transistor that operates at high speed.

A gate line GT1 may extend in the vertical direction Z from the top of the first layer L1 and may be disposed to surround the first active region 11 and the second active region 12. The gate contact CB may be disposed on the gate line GT1. The gate line GT1 may be defined as a conductive segment containing a conductive material such as polysilicon or one or more metals. The length of the gate line GT1 in the second direction Y may vary according to embodiments.

The via structure 13 may extend in the vertical direction Z on the second active region 12, and the source/drain region of the first active region 11 and the source/drain region of the second active region 12 may be electrically connected to each other through the via structure 13. For example, the via structure 13 may penetrate through the first active region 11 and be connected to the first contact CA1. According to embodiments, a second contact may be disposed on the second active region 12, and the via structure 13 may be disposed on the second contact.

The front wiring layer M1 may further include frontside signal lines M1c and M1d arranged between the frontside power rails M1a and M1b. At this time, the frontside signal lines M1c and M1d may be used as signal wires. The number of signal wires arranged between the frontside power rails M1a and M1b may vary according to embodiments. A frontside signal line M1c may be electrically connected to the gate line GT1 through the gate contact CB. For example, the frontside signal line M1c may transmit the input signal IN of FIG. 3 to the gate line GT1. A frontside signal line M1d may be electrically connected to the source/drain region of the first active region 11 through a frontside via VA and the first contact CA1. For example, the frontside signal line M1d may receive the output signal OUT of FIG. 3 from the source/drain region of the first active region 11.

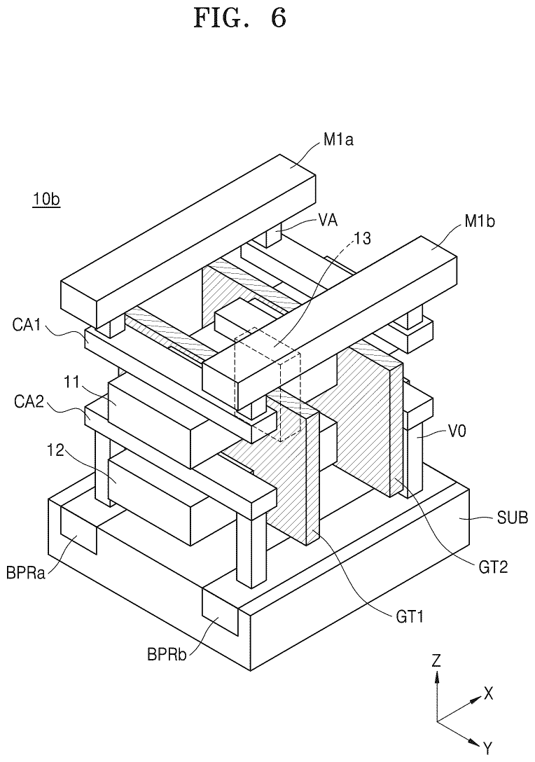

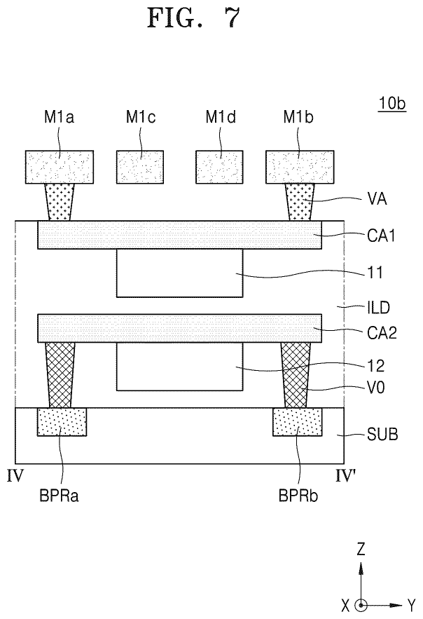

FIG. 6 is a schematic perspective view of an integrated circuit 10b according to an embodiment. FIG. 7 is a cross-sectional view of the integrated circuit 10b of FIG. 6, according to an embodiment.

Referring to FIGS. 6 and 7 together, the integrated circuit 10b may include a substrate SUB, the first active region 11, the second active region 12, the gate lines GT1 and GT2, the first contacts CA1, the second contacts CA2, the via structure 13, the frontside vias VA, vias V0, the frontside power rails M1a and M1b, and buried power rails BPRa and BPRb. The integrated circuit 10b corresponds to a modified example of the integrated circuit 10a of FIG. 2, and descriptions given above with reference to FIGS. 2 to 5B may be applied to the present embodiment. According to embodiments, one of the frontside power rails M1a and M1b may be omitted. Also, according to embodiments, one of the buried power rails BPRa and BPRb may be omitted.

The buried power rails BPRa and BPRb may be buried in the substrate SUB, each extend in the first direction X, and be spaced apart from each other in the second direction Y. The vias V0 may be arranged on the buried power rails BPRa and BPRb, respectively, and may extend in the vertical direction Z. The buried power rails BPRa and BPRb may be electrically connected to the second contact CA2 through the vias V0. For example, the buried power rails BPRa and BPRb may be at least partially overlapped by the frontside power rails M1a and M1b in the vertical direction Z, respectively. For example, the buried power rails BPRa and BPRb may be aligned in the vertical direction Z with respect to the frontside power rails M1a and M1b.

According to an embodiment, the buried power rails BPRa and BPRb may receive the ground voltage VSS, and the frontside power rails M1a and M1b may receive the power voltage VDD. At this time, the first active region 11, the gate lines GT1 and GT2, and the first contacts CA1 may correspond to the PFET of FIG. 1A, and the second active region 12, the gate lines GT1 and GT2, and the second contacts CA2 may correspond to the NFET of FIG. 1A.

According to an embodiment, the buried power rails BPRa and BPRb may receive the power voltage VDD, and the frontside power rails M1a and M1b may receive the ground voltage VSS. At this time, the first active region 11, the gate lines GT1 and GT2, and the first contacts CA1 may correspond to the NFET of FIG. 1B, and the second active region 12, the gate lines GT1 and GT2, and the second contacts CA2 may correspond to the PFET of FIG. 1B.

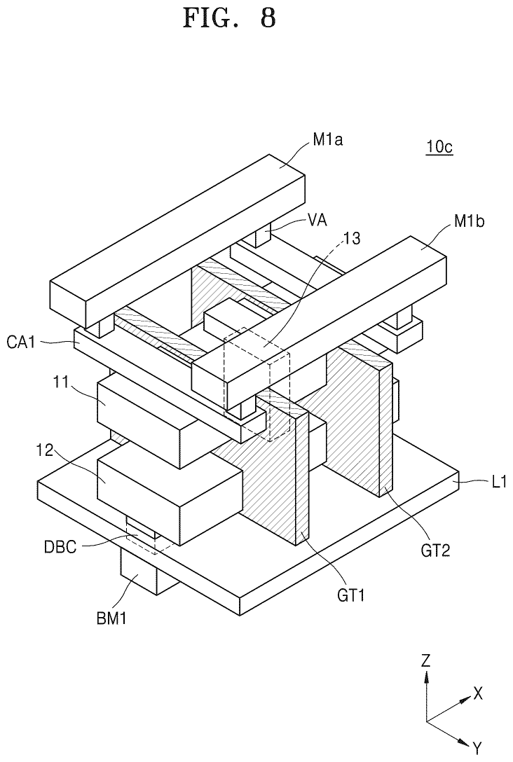

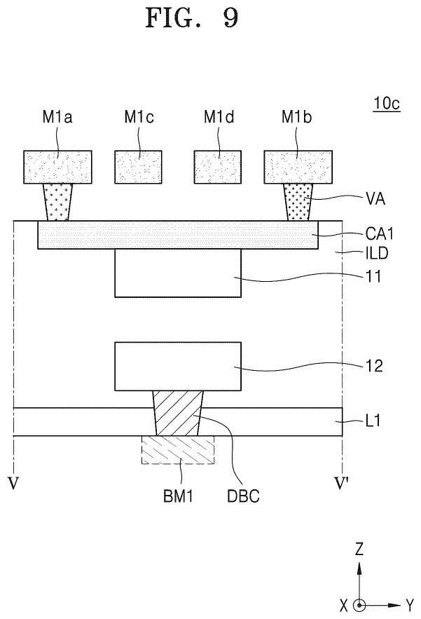

FIG. 8 is a schematic perspective view of an integrated circuit 10c according to an embodiment. FIG. 9 is a cross-sectional view of the integrated circuit 10c of FIG. 8, according to an embodiment.

Referring to FIGS. 8 and 9 together, the integrated circuit 10c may include the first layer L1, the first active region 11, the second active region 12, the gate lines GT1 and GT2, and the first contacts CA1, the via structure 13, the frontside vias VA, direct backside contacts DBC, the frontside power rails M1a and M1b, and the backside wiring layer BM1. The integrated circuit 10c corresponds to a modified example of the integrated circuit 10a of FIG. 2, and descriptions given above with reference to FIGS. 2 to 5B may be applied to the present embodiment. According to embodiments, one of the frontside power rails M1a and M1b may be omitted.

The backside wiring layer BM1 may be disposed on the back side of the first layer L1 and may extend in the first direction X. At this time, the backside wiring layer BM1 may be overlapped by the second active region 12 in the vertical direction Z. Also, the backside wiring layer BM1 may not be overlapped by the frontside power rails M1a and M1b in the vertical direction Z. The direct backside contacts DBC may be arranged on the backside wiring layer BM1 and extend in the vertical direction Z and penetrate through the first layer L1. Therefore, the backside wiring layer BM1 may be directly connected to the source/drain regions of the second active region 12 through the direct backside contacts DBC. According to embodiments, a via and/or a contact may be further arranged between each direct backside contact DBC and the source/drain region and/or between the backside wiring layer BM1 and each direct back contact DBC.

According to an embodiment, the backside wiring layer BM1 may receive the ground voltage VSS, and the frontside power rails M1a and M1b may receive the power voltage VDD. At this time, the first active region 11, the gate lines GT1 and GT2, and the first contacts CA1 may correspond to the PFET of FIG. 1A, and the second active region 12, the gate lines GT1 and GT2, and the second contacts CA2 may correspond to the NFET of FIG. 1A.

According to an embodiment, the backside wiring layer BM1 may receive the power voltage VDD, and the frontside power rails M1a and M1b may receive the ground voltage VSS. At this time, the first active region 11, the gate lines GT1 and GT2, and the first contacts CA1 may correspond to the NFET of FIG. 1B, and the second active region 12, the gate lines GT1 and GT2, and the second contacts CA2 may correspond to the PFET of FIG. 1B.

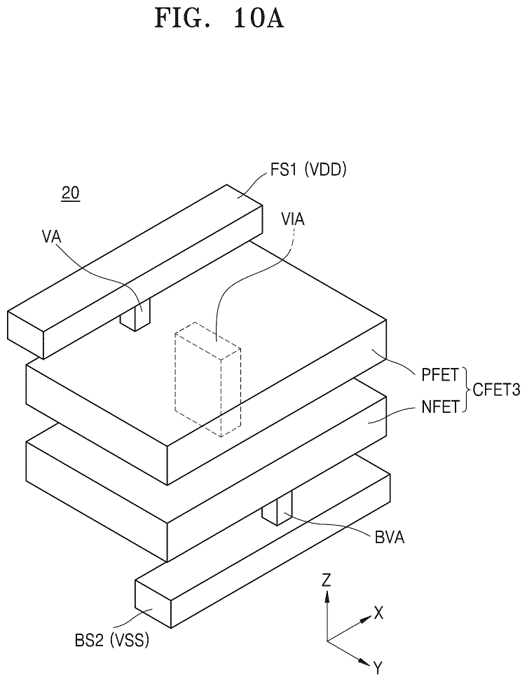

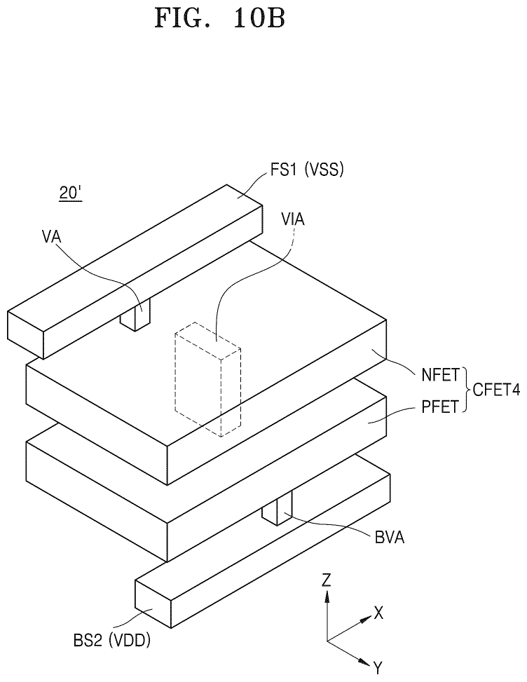

FIG. 10A is a schematic perspective view of an integrated circuit 20 according to an embodiment.

Referring to FIG. 10A, the integrated circuit 20 may include a CFET CFET3. The CFET CFET3 may include a PFET and an NFET arranged in the vertical direction Z. According to an embodiment, the PFET may be disposed above the NFET in the vertical direction Z. The PFET and the NFET may be connected to each other through a via structure VIA extending in the vertical direction Z from the top of the NFET. According to an embodiment, the CFET CFET3 may be implemented as a standard cell. The integrated circuit 20 corresponds to a modified example of the integrated circuit 10 of FIG. 1A, and descriptions given above with reference to FIG. 1A may be applied to the present embodiment.

The integrated circuit 20 may implement a PDN by using a frontside power rail FS1 disposed on the front side of a substrate and a backside power rail BS2 disposed on the back side of the substrate. For example, the frontside power rail FS1 may receive a positive supply voltage, e.g., the power voltage VDD, and the backside power rail BS2 may receive a negative supply voltage, e.g., the ground voltage VSS. The backside power rail BS2 may provide the ground voltage VSS to the NFET through the backside via BVA, and the frontside power rail FS1 may provide the power voltage VDD to the PFET through the frontside via VA.

FIG. 10B is a schematic perspective view of an integrated circuit 20′ according to an embodiment.

Referring to FIG. 1B, the integrated circuit 20′ corresponds to a modified example of the integrated circuit 20 of FIG. 10A, and descriptions given above with reference to FIG. 10A may be applied to the present embodiment. The integrated circuit 20′ may include a CFET CFET4. The CFET CFET4 may include an NFET and a PFET arranged in the vertical direction Z. According to an embodiment, the NFET may be disposed above the PFET in the vertical direction Z. According to an embodiment, the CFET CFET4 may be implemented as a standard cell. The NFET and the PFET may be connected to each other through a via structure VIA extending in the vertical direction Z from the top of the PFET.

For example, the frontside power rail FS1 may receive a negative supply voltage, e.g., the ground voltage VSS, and the backside power rail BS2 may receive a positive supply voltage, e.g., the power voltage VDD. The backside power rail BS2 may provide the power voltage VDD to the PFET through the backside vias BVA, and the frontside power rail FS1 may provide the ground voltage VSS to the NFET through the frontside via VA.

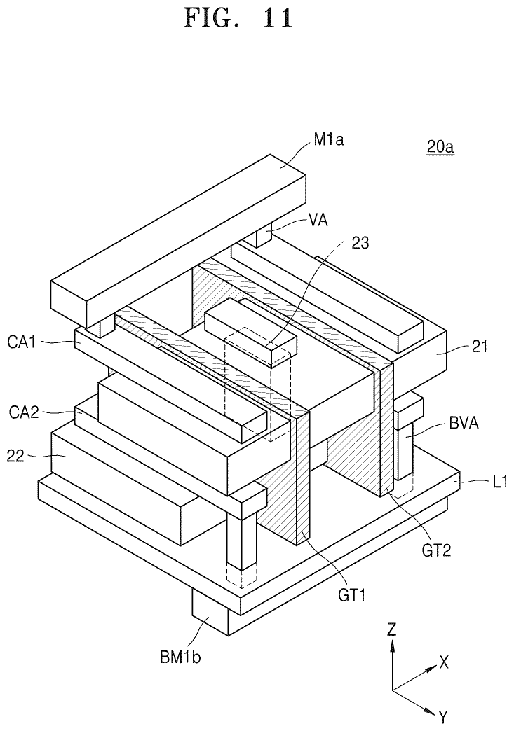

FIG. 11 is a perspective view of an integrated circuit 20a according to an embodiment.

Referring to FIG. 11, the integrated circuit 20a corresponds to an implementation example of the integrated circuit 20 of FIG. 10A or the integrated circuit 20′ of FIG. 10B, and descriptions given above with reference to FIGS. 10A and 10B may be applied to the present embodiment. The integrated circuit 20a may include the first layer L1, a first active region 21, a second active region 22, the gate lines GT1 and GT2, the first contacts CA1, the second contacts CA2, a via structure 23, the frontside vias VA, the backside vias BVA, a frontside power rail M1a, and a backside power rail BM1b.

According to an embodiment, the first active region 21, the gate lines GT1 and GT2, and the first contacts CA1 may correspond to the PFET of FIG. 10A, and the second active region 22, the gate lines GT1 and GT2, and the second contacts CA2 may correspond to the NFET of FIG. 10A. According to an embodiment, the first active region 21, the gate lines GT1 and GT2, and the first contacts CA1 may correspond to the NFET of FIG. 10B, and the second active region 22, the gate lines GT1 and GT2, and the second contacts CA2 may correspond to the PFET of FIG. 10B.

The second active region 22 may be disposed on the front side of the first layer L1, and the first active region 21 may be disposed above the second active region 22 in the vertical direction Z. Each of the gate lines GT1 and GT2 may extend in the vertical direction Z and be arranged to surround the first active region 21 and the second active region 22. The first contacts CA1 may be arranged on the first active region 21 and may each extend in the second direction Y. The second contacts CA2 may be arranged on the second active region 22 and may each extend in the second direction Y.

According to an embodiment, the first active region 21 may at least partially overlap the backside power rail BM1b in the vertical direction Z. According to an embodiment, the second active region 22 may at least partially overlap the frontside power rail M1a in the vertical direction Z. In this way, by increasing the size of each of the first active region 21 and the second active region 22, the driving strength of the first transistor and the second transistor respectively formed on the first active region 21 and the second active region 22 may be improved, and thus the first transistor and the second transistor may be implemented as high-performance transistors.

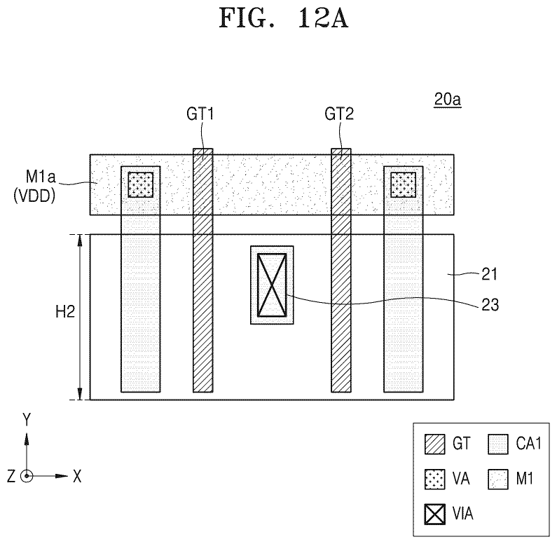

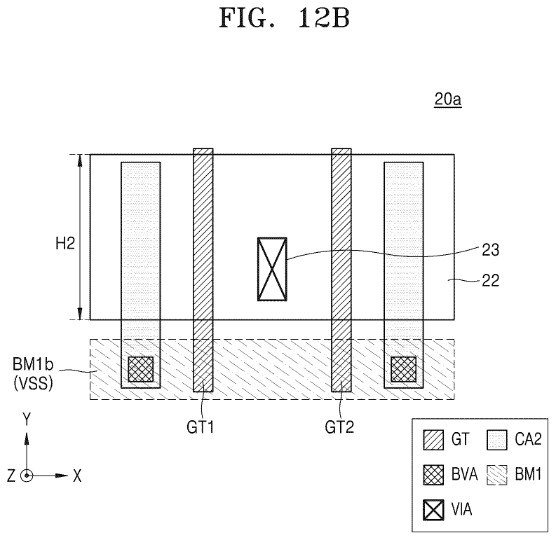

FIG. 12A shows a layout corresponding to the upper transistor of the integrated circuit 20a of FIG. 11, according to an embodiment.

Referring to FIG. 12A, the integrated circuit 20a may include the first active region 21, the gate lines GT1 and GT2, the first contacts CA1, the frontside vias VA, the frontside wiring layer M1, and the via structure 23. The first active region 21 may extend in the first direction X and have a second height H2 in the second direction Y. The frontside wiring layer M1 may include the frontside power rail M1a extending in the first direction X. For example, the frontside power rail M1a may receive the power voltage VDD, and the first active region 21, the first contacts CA1, and the gate lines GT1 and GT2 may constitute the P-type transistor PM of FIG. 3.

FIG. 12B shows a layout corresponding to the lower transistor of integrated circuit 20a of FIG. 11, according to an embodiment.

Referring to FIG. 12B, the integrated circuit 20a may include the second active region 22, the gate lines GT1 and GT2, the second contacts CA2, a backside wiring layer BM1, the via structure 23, and the backside vias BVA. The second active region 22 may extend in the first direction X and have a second height H2 in the second direction Y. The backside wiring layer BM1 may include the backside power rail BM1b extending in the first direction X. For example, the backside power rail BM1b may receive the ground voltage VSS, and the second active region 22, the second contacts CA2, and the gate lines GT1 and GT2 may constitute the N-type transistor NM of FIG. 3.

The gate lines GT1 and GT2 may each extend in the vertical direction Z, and thus the upper transistor and the lower transistor of the integrated circuit 20a may share the gate lines GT1 and GT2. The via structure 23 may extend in the vertical direction Z, and thus the source/drain region of the first active region 21 may be electrically connected to the source/drain region of the second active region 22.

According to an embodiment, the second height H2 of each of the first active region 21 and the second active region 22 may be greater than the first height H1 of FIGS. 4A and 4B. The integrated circuit 10a of FIGS. 4A and 4B includes two power rails, e.g., the frontside power rails M1a and M1b, above the CFET and two power rails, e.g., the backside power rails BM1a and BM1b, below the CFET. On the other hand, the integrated circuit 20a according to the present embodiment may include one power rail, e.g., the frontside power rail M1a, above the CFET and one power rail, e.g., the backside power rail BM1b, below the CFET.

Therefore, the first active region 21 and the second active region 22 may each be formed to have the second height H2 that is greater than the first height H1 of FIGS. 4A and 4B. In this way, the driving strength of the integrated circuit 20a may be improved by increasing the sizes of the first active region 21 and the second active region 22. However, the disclosure is not limited thereto. According to one or more embodiments, the second height H2 may not be greater than the first height H1. In this case, the size of the integrated circuit 20a may be reduced.

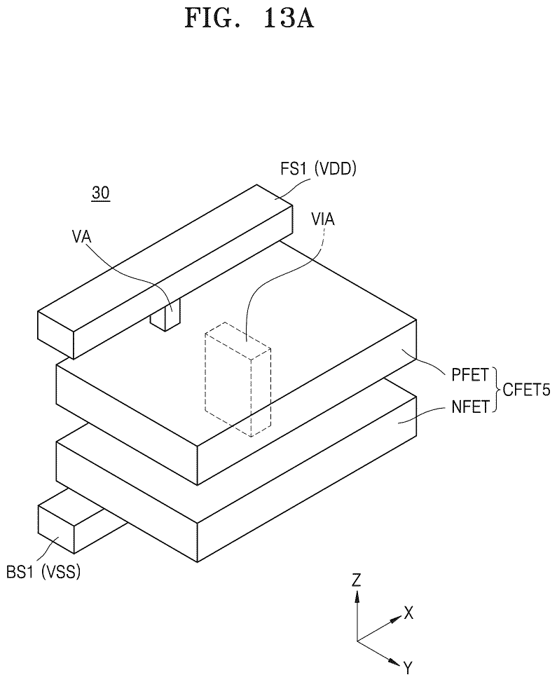

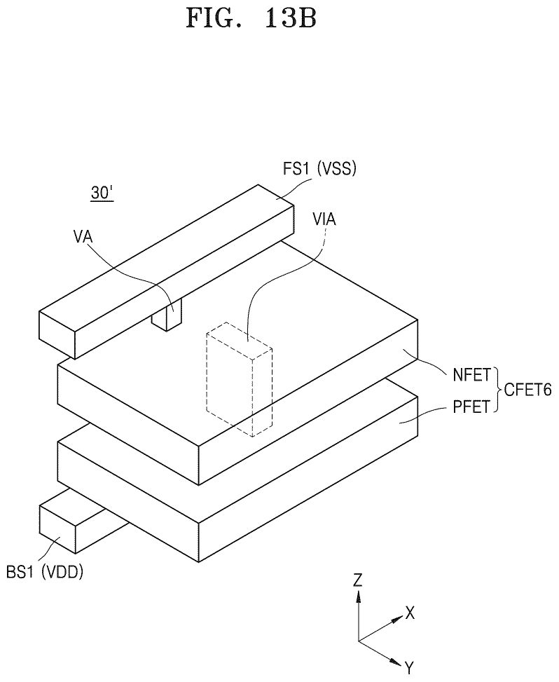

FIG. 13A is a schematic perspective view of an integrated circuit 30 according to an embodiment.

Referring to FIG. 13A, the integrated circuit 30 may include a CFET CFET5. The CFET CFET5 may include a PFET and an NFET arranged in the vertical direction Z. According to an embodiment, the PFET may be disposed above the NFET in the vertical direction Z. The PFET and the NFET may be connected to each other through a via structure VIA extending in the vertical direction Z from the top of the NFET. According to an embodiment, the CFET CFET5 may be implemented as a standard cell. The integrated circuit 30 corresponds to a modified example of the integrated circuit 10 of FIG. 1A, and descriptions given above with reference to FIG. 1A may be applied to the present embodiment.

The integrated circuit 30 may implement a PDN by using a frontside power rail FS1 disposed on the front side of a substrate and a backside power rail BS1 disposed on the back side of the substrate. For example, the frontside power rail FS1 may receive a positive supply voltage, e.g., the power voltage VDD, and the backside power rail BS1 may receive a negative supply voltage, e.g., the ground voltage VSS. The backside power rail BS1 may provide the ground voltage VSS to the NFET through the backside via BVA, and the frontside power rail FS1 may provide the power voltage VDD to the PFET through the frontside via VA.

FIG. 13B is a schematic perspective view of an integrated circuit 30′ according to an embodiment.

Referring to FIG. 13B, the integrated circuit 30′ corresponds to a modified example of the integrated circuit 30 of FIG. 13A, and descriptions given above with reference to FIG. 13A may be applied to the present embodiment. The integrated circuit 30′ may include a CFET CFET6. The CFET CFET6 may include an NFET and a PFET arranged in the vertical direction Z. According to an embodiment, the NFET may be disposed above the PFET in the vertical direction Z. According to an embodiment, the CFET CFET6 may be implemented as a standard cell. The NFET and the PFET may be connected to each other through a via structure VIA extending in the vertical direction Z from the top of the PFET.

For example, the frontside power rail FS1 may receive a negative supply voltage, e.g., the ground voltage VSS, and the backside power rail BS1 may receive a positive supply voltage, e.g., the power voltage VDD. The backside power rail BS1 may provide the power voltage VDD to the PFET through the backside via BVA, and the frontside power rail FS1 may provide the ground voltage VSS to the NFET through the frontside via VA.

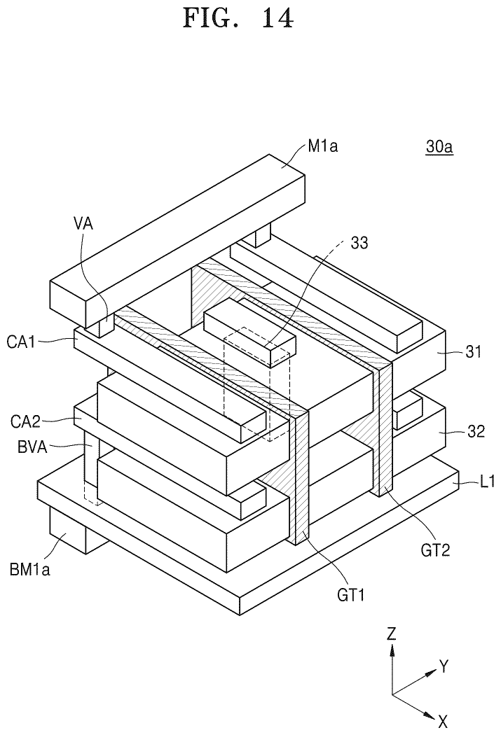

FIG. 14 is a perspective view of an integrated circuit 30a according to an embodiment.

Referring to FIG. 14, the integrated circuit 30a corresponds to an implementation example of the integrated circuit 30 of FIG. 13A or the integrated circuit 30′ of FIG. 13B, and descriptions given above with reference to FIGS. 13A and 13B may be applied to the present embodiment. The integrated circuit 30a may include the first layer L1, a first active region 31, a second active region 32, the gate lines GT1 and GT2, the first contacts CA1, the second contacts CA2, a via structure 33, the frontside vias VA, the backside vias BVA, a frontside power rail M1a, and a backside power rail BM1a.

According to an embodiment, the first active region 31, the gate lines GT1 and GT2, and the first contacts CA1 may correspond to the PFET of FIG. 13A, and the second active region 32, the gate lines GT1 and GT2, and the second contacts CA2 may correspond to the NFET of FIG. 13A. According to an embodiment, the first active region 31, the gate lines GT1 and GT2, and the first contacts CA1 may correspond to the NFET of FIG. 13B, and the second active region 32, the gate lines GT1 and GT2, and the second contacts CA2 may correspond to the PFET of FIG. 13B.

The second active region 32 may be disposed on the front side of the first layer L1, and the first active region 31 may be disposed above the second active region 32 in the vertical direction Z. Each of the gate lines GT1 and GT2 may extend in the vertical direction Z and be arranged to surround the first active region 31 and the second active region 32. The first contacts CA1 may be arranged on the first active region 31 and may each extend in the second direction Y. The second contacts CA2 may be arranged on the second active region 32 and may each extend in the second direction Y.

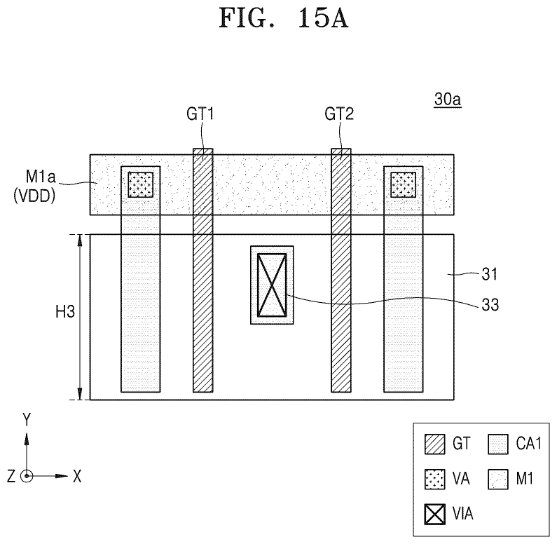

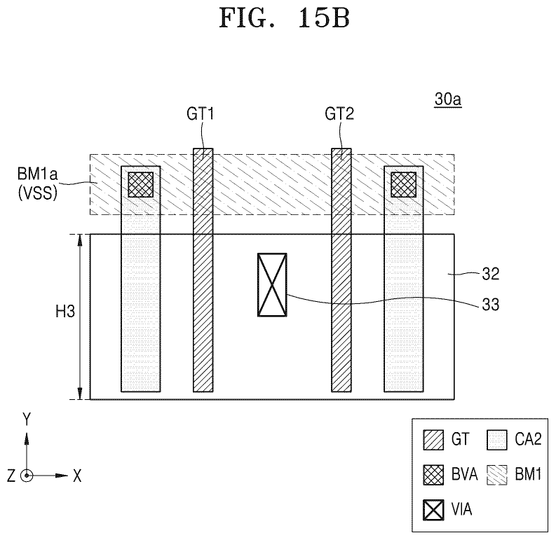

FIG. 15A shows a layout corresponding to the upper transistor of the integrated circuit 30a of FIG. 14, according to an embodiment.

Referring to FIG. 15A, the integrated circuit 30a may include the first active region 31, the gate lines GT1 and GT2, the first contacts CA1, the frontside vias VA, the frontside wiring layer M1, and the via structure 33. The first active region 31 may extend in the first direction X and have a third height H3 in the second direction Y. The frontside wiring layer M1 may include the frontside power rail M1a extending in the first direction X. For example, the frontside power rail M1a may receive the power voltage VDD, and the first active region 31, the first contacts CA1, and the gate lines GT1 and GT2 may constitute the P-type transistor PM of FIG. 3.

FIG. 15B shows a layout corresponding to the lower transistor of the integrated circuit 30a of FIG. 14, according to an embodiment.

Referring to FIG. 15B, the integrated circuit 30a may include the second active region 32, the gate lines GT1 and GT2, the second contacts CA2, the backside wiring layer BM1, the via structure 33, and the backside vias BVA. The second active region 32 may extend in the first direction X and have the third height H3 in the second direction Y. The backside wiring layer BM1 may include the backside power rail BM1a extending in the first direction X. For example, the backside power rail BM1a may receive the ground voltage VSS, and the second active region 32, the second contacts CA2, and the gate lines GT1 and GT2 may constitute the N-type transistor NM of FIG. 3.

The gate lines GT1 and GT2 may each extend in the vertical direction Z, and thus the upper transistor and the lower transistor of the integrated circuit 30a may share the gate lines GT1 and GT2. The via structure 33 may extend in the vertical direction Z, and thus the source/drain region of the first active region 31 may be electrically connected to the source/drain region of the second active region 32. According to an embodiment, the backside power rail BM1a may be at least partially overlapped by the frontside power rail M1a in the vertical direction Z. For example, the backside power rail BM1a may be aligned with respect to the frontside power rail M1a in the vertical direction Z.

According to an embodiment, the third height H3 of each of the first active region 31 and the second active region 32 may be greater than the first height H1 of FIGS. 4A and 4B. The integrated circuit 10a of FIGS. 4A and 4B includes two power rails, e.g., the frontside power rails M1a and M1b, above the CFET and two power rails, e.g., the backside power rails BM1a and BM1b, below the CFET. On the other hand, the integrated circuit 30a according to the present embodiment may include one power rail, e.g., the frontside power rail M1a, above the CFET and one power rail, e.g., the backside power rail BM1a, below the CFET. Therefore, the first active region 31 and the second active region 32 may each be formed to have the third height H3 that is greater than the first height H1 of FIGS. 4A and 4B. In this way, the driving strength of the integrated circuit 30a may be improved by increasing the sizes of the first active region 31 and the second active region 32. However, the disclosure is not limited thereto. According to one or more embodiments, the third height H3 may not be greater than the first height H1. In this case, the size of the integrated circuit 30a may be reduced.

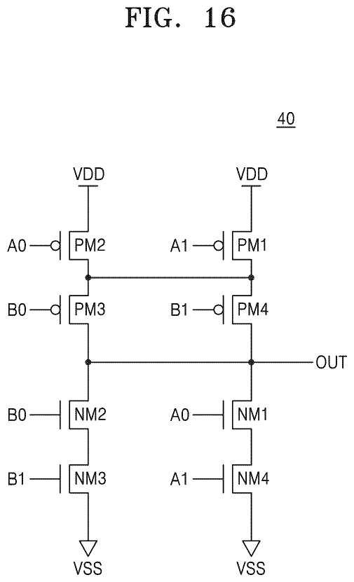

FIG. 16 is a circuit diagram showing an integrated circuit 40 according to an embodiment.

Referring to FIG. 16, the integrated circuit 40 may correspond to an AOI22 cell including first to fourth P-type transistors PM1 to PM4 and first to fourth N-type transistors NM1 to NM4. The first P-type transistor PM1 may include a source that receives the power voltage VDD and a gate that receives an input signal A1, and the second P-type transistor PM2 may include a source that receives the power voltage VDD and a gate that receives an input signal A0. The third P-type transistor PM3 may include a gate that receives an input signal B0 and a drain that provides the output signal OUT, and the fourth P-type transistor PM4 may include a gate that receives an input signal B1 and a drain that provides the output signal OUT. At this time, the first P-type transistor PM1 and the fourth P-type transistor PM4 may be connected to each other in series, and the second P-type transistor PM2 and the third P-type transistor PM3 may be connected to each other in series.

The first N-type transistor NM1 may include a gate that receives an input signal A00 and a drain that provides the output signal OUT, and the second N-type transistor NM2 may include a gate that receives an input signal B0 and a drain that provides the output signal OUT. The third N-type transistor NM3 may include a gate that receives the input signal B1 and a source that receives the ground voltage VSS, and the fourth N-type transistor NM4 may include a gate that receives the input signal A1 and a source connected to the ground voltage VSS. At this time, the first N-type transistor NM1 and the fourth N-type transistor NM4 may be connected to each other in series, and the second N-type transistor NM2 and the third N-type transistor NM3 may be connected to each other in series. For example, the first to fourth P-type transistors PM1 to PM4 and the first to fourth N-type transistors NM1 to NM4 may be implemented as CFETs.

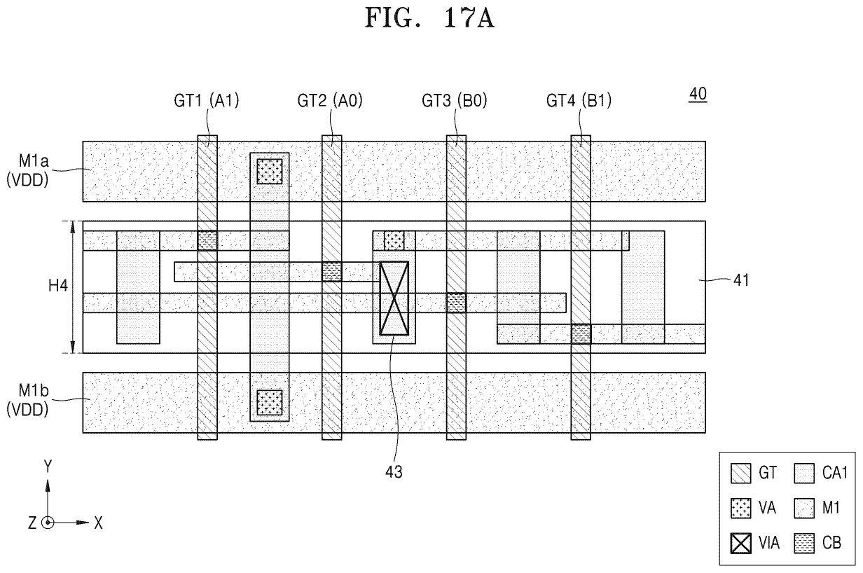

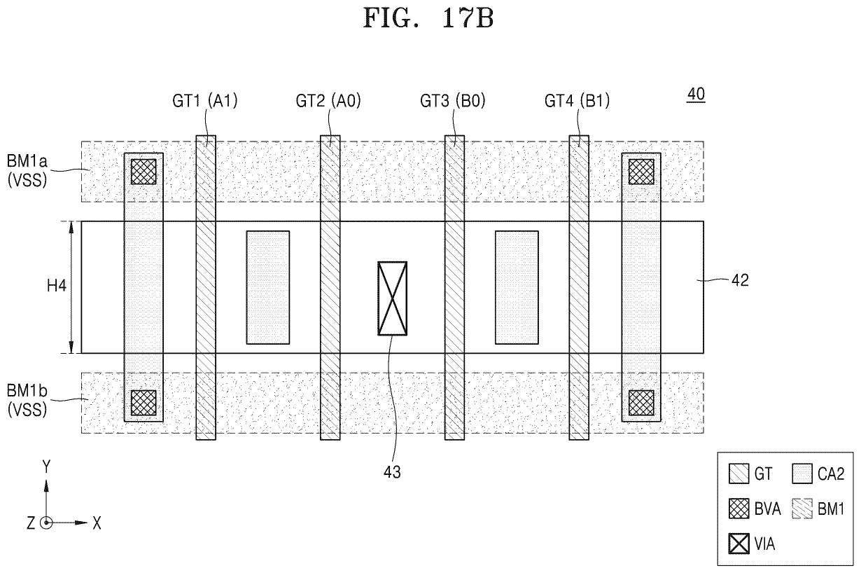

FIGS. 17A and 17B show layouts of the integrated circuit 40 of FIG. 16, according to an embodiment. At this time, FIG. 17A corresponds to the layout of an upper transistor of a CFET included in the integrated circuit 40, and FIG. 17B corresponds to the layout of a lower transistor of the CFET included in the integrated circuit 40.

Referring to FIG. 17A, the integrated circuit 40 may include a first active region 41, gate lines GT1 to GT4, the first contacts CA1, the frontside vias VA, gate contacts CB, the frontside wiring layer M1, and a via structure 43. The frontside wiring layer M1 may include the frontside power rails M1a and M1b, each extending in the first direction X. For example, the frontside power rails M1a and M1b may receive the power voltage VDD, and the first active region 41, the first contacts CA1, and the gate lines GT1 to GT4 may constitute the first to fourth P-type transistors PM1 to PM4 of FIG. 16. Also, the frontside wiring layer M1 may further include a plurality of signal lines between the frontside power rails M1a and M1b.

The first active region 41 may extend in the first direction X and have a fourth height H4 in the second direction Y. According to an embodiment, the fourth height H4 may be substantially identical to the first height H1 of FIG. 4A, but the disclosure is not limited thereto. The gate contacts CB may be arranged on the gate lines GT1 to GT4, respectively. For example, the gate line GT1 may receive the input signal A1 through the gate contact CB, the gate line GT2 may receive the input signal A0 through the gate contact CB, the gate line GT3 may receive the input signal B0 through the gate contact CB, and the gate line GT4 may receive the input signal B1 through the gate contact CB.

Referring to FIG. 17B, the integrated circuit 40 may include a second active region 42, the gate lines GT1 to GT4, the second contacts CA2, the backside wiring layer BM1, the via structure 43, and the backside vias BVA. The second active region 42 may extend in the first direction X and have the fourth height H4 in the second direction Y. The backside wiring layer BM1 may include the backside power rails BM1a and BM1b, each extending in the first direction X. For example, the backside power rails BM1a and BM1b may receive the ground voltage VSS, and the second active region 42, the second contacts CA2, and the gate lines GT1 to GT4 may constitute the first to fourth N-type transistors NM1 to NM4 of FIG. 16.

The gate lines GT1 to GT4 may each extend in the vertical direction Z, and thus the upper transistor and the lower transistor of the integrated circuit 40 may share the gate lines GT1 to GT4. The via structure 43 may extend in the vertical direction Z, and thus the source/drain region of the first active region 41 may be electrically connected to the source/drain region of the second active region 42. According to an embodiment, the backside power rails BM1a and BM1b may be at least partially overlapped by the frontside power rails M1a and M1b in the vertical direction Z, respectively. For example, the backside power rails BM1a and BM1b may be aligned with respect to the frontside power rails M1a and M1b in the vertical direction Z, respectively.

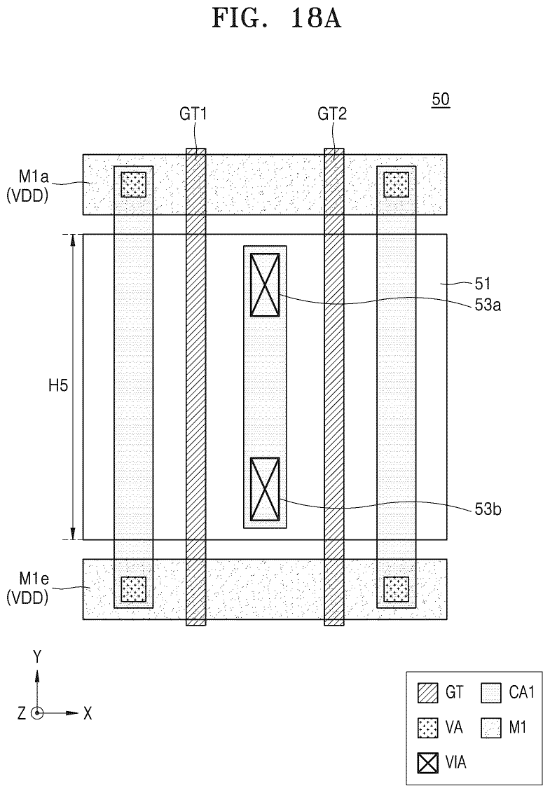

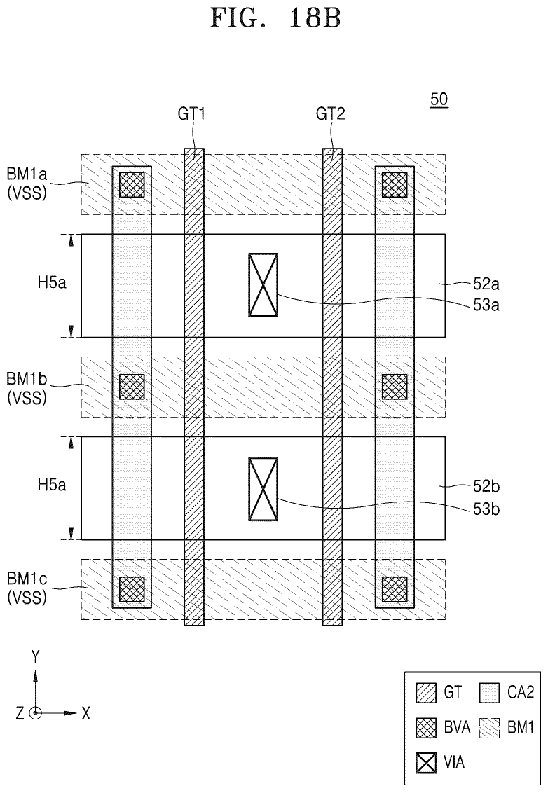

FIGS. 18A and 18B show layouts of an integrated circuit 50 according to an embodiment. At this time, FIG. 18A corresponds to the layout of an upper transistor of a CFET included in the integrated circuit 50, and FIG. 18B corresponds to the layout of a lower transistor of the CFET included in the integrated circuit 50.

Referring to FIG. 18A, the integrated circuit 50 may include a first active region 51, the gate lines GT1 and GT2, the first contacts CA1, the frontside vias VA, the frontside wiring layer M1, and via structures 53a and 53b. The first active region 51 may extend in the first direction X and have a fifth height H5 in the second direction Y. The frontside wiring layer M1 may include frontside power rails M1a and M1e, each extending in the first direction X. At this time, the integrated circuit 50 may include multi-height cells.

Referring to FIG. 18B, the integrated circuit 50 may include second active regions 52a and 52b, the gate lines GT1 and GT2, the second contacts CA2, the backside vias BVA, the backside wiring layer BM1, and the via structures 53a and 53b. The second active regions 52a and 52b may each extend in the first direction X and be spaced apart from each other in the second direction Y. At this time, the second active regions 52a and 52b may each have a fifth height H5a in the second direction Y. The backside wiring layer BM1 may include backside power rails BM1a, BM1b, and BM1c each extending in the first direction X. According to embodiments, a lower transistor of a CFET may be connected to backside power rails through a DBC of the CFET, and the present embodiment may be modified according to the embodiment shown in FIGS. 8 and 9.

According to an embodiment, the frontside power rails M1a and M1e may receive the power voltage VDD, and the first active region 51, the first contacts CA1, and the gate lines GT1 and GT2 may constitute a PFET included in a CFET. Also, the backside power rails BM1a, BM1b, and BM1c may receive the ground voltage VSS, and the second active regions 52a and 52b, the second contacts CA2, and the gate lines GT1 and GT2 may constitute an NFET included in the CFET.

However, the disclosure is not limited thereto. According to one or more embodiments, the frontside power rails M1a and M1e may receive the ground voltage VSS, and the first active region 51, the first contacts CA1, and the gate lines GT1 and GT2 may constitute an NFET included in the CFET. Also, the backside power rails BM1a, BM1b, and BM1c may receive the power voltage VDD, and the second active regions 52a and 52b, the second contacts CA2, and the gate lines GT1 and GT2 may constitute a PFET included in the CFET.

The gate lines GT1 and GT2 may each extend in the vertical direction Z, and thus the upper transistor and the lower transistor of the integrated circuit 50 may share the gate lines GT1 and GT2. The via structures 53a and 53b may each extend in the vertical direction Z, and thus source/drain regions of the first active region 51 may be electrically connected to source/drain regions of the second active regions 52a and 52b. According to an embodiment, the backside power rail BM1a may be at least partially overlapped by the frontside power rail M1a in the vertical direction Z, and a backside power rail BM1c may be at least partially overlapped by a frontside power rail M1e in the vertical direction Z.

According to an embodiment, the fifth height H5 of the first active region 51 may be greater than the fifth height H5a of each of the second active regions 52a and 52b. For example, the fifth height H5 may be greater than twice the fifth height H5a. Therefore, an upper transistor (e.g., a PFET) of a CFET may be implemented as a high-performance transistor, and a lower transistor (e.g., an NFET) of the CFET may be implemented as a high-speed transistor.

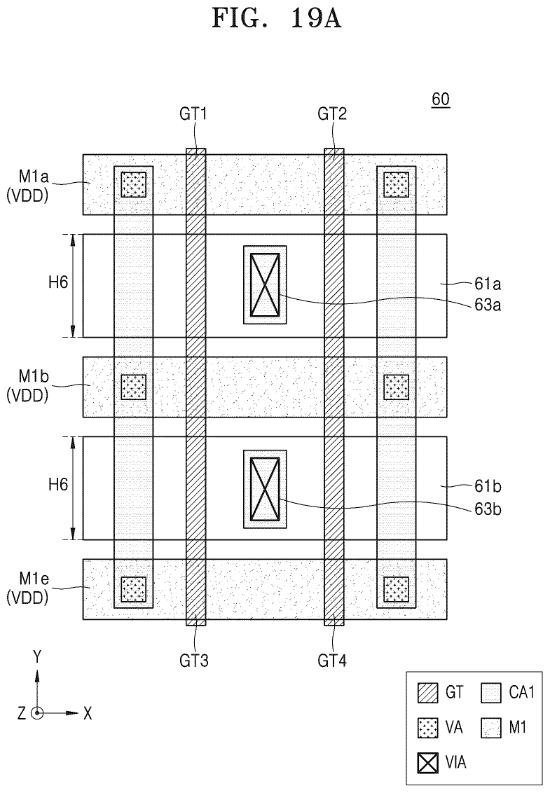

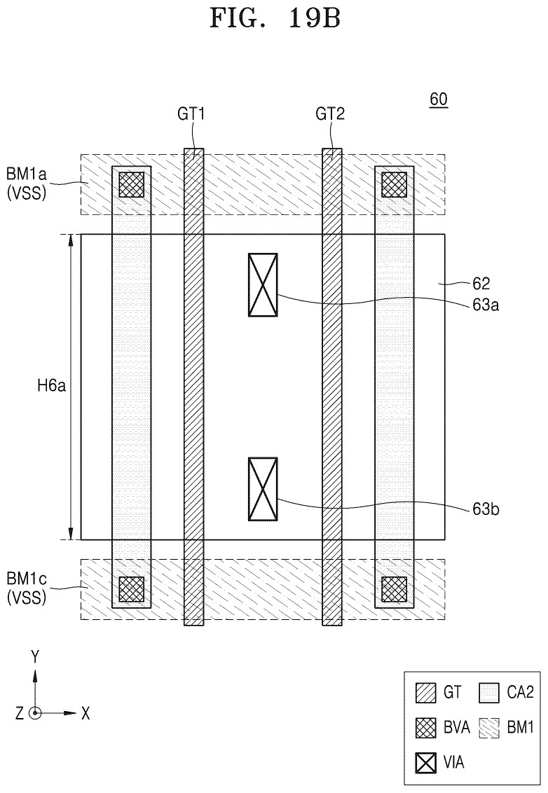

FIGS. 19A and 19B show layouts of an integrated circuit 60 according to an embodiment. At this time, FIG. 19A corresponds to the layout of an upper transistor of a CFET included in the integrated circuit 60, and FIG. 19B corresponds to the layout of a lower transistor of the CFET included in the integrated circuit 60.

Referring to FIG. 19A, the integrated circuit 60 may include first active regions 61a and 61b, the gate lines GT1 and GT2, the first contacts CA1, the frontside vias VA, the frontside wiring layer M1, and via structures 63a and 63b. The first active regions 61a and 61b may each extend in the first direction X and be spaced apart from each other in the second direction Y. At this time, the first active regions 61a and 61b may each have a sixth height H6 in the second direction Y. The frontside wiring layer M1 may include frontside power rails M1a, M1b, and M1e, each extending in the first direction X. At this time, the integrated circuit 60 may include multi-height cells.

Referring to FIG. 19B, the integrated circuit 60 may include a second active region 62, the gate lines GT1 and GT2, the second contacts CA2, the backside vias BVA, the backside wiring layer BM1, and the via structures 63a and 63b. The second active region 62 may extend in the first direction X and have a sixth height H6a in the second direction Y. The backside wiring layer BM1 may include backside power rails BM1a and BM1c, each extending in the first direction X. According to embodiments, a lower transistor of a CFET may be connected to backside power rails through a DBC of the CFET, and the present embodiment may be modified according to the embodiment shown in FIGS. 8 and 9.

According to an embodiment, the frontside power rails M1a, M1b, and M1e may receive the power voltage VDD, and the first active regions 61a and 61b, the first contacts CA1, and the gate lines GT1 and GT2 may constitute a PFET included in a CFET. Also, the backside power rails BM1a and BM1c may receive the ground voltage VSS, and the second active region 62, the second contacts CA2, and the gate lines GT1 and GT2 may constitute an NFET included in the CFET.

However, the disclosure is not limited thereto. According to one or more embodiments, the frontside power rails M1a, M1b, and M1e may receive the ground voltage VSS, and the first active regions 61a and 61b, the first contacts CA1, and the gate lines GT1 and GT2 may constitute an NFET included in the CFET. Also, the backside power rails BM1a and BM1c may receive the power voltage VDD, and the second active region 62, the second contacts CA2, and the gate lines GT1 and GT2 may constitute a PFET included in the CFET.

The gate lines GT1 and GT2 may each extend in the vertical direction Z, and thus the upper transistor and the lower transistor of the integrated circuit 60 may share the gate lines GT1 and GT2. The via structures 63a and 63b may each extend in the vertical direction Z, and thus source/drain regions of the first active region 61 may be electrically connected to source/drain regions of the second active region 62. According to an embodiment, the backside power rail BM1a may at least partially overlap the frontside power rail M1a in the vertical direction Z, and a backside power rail BM1c may at least partially overlap a frontside power rail M1e in the vertical direction Z.

According to an embodiment, the sixth height H6a of the second active region 62 may be greater than the sixth height H6 of each of the first active regions 61a and 61b. For example, the sixth height H6a may be greater than twice the sixth height H6. Therefore, an upper transistor (e.g., a PFET) of a CFET may be implemented as a high-speed transistor, and a lower transistor (e.g., an NFET) of the CFET may be implemented as a high-performance transistor.

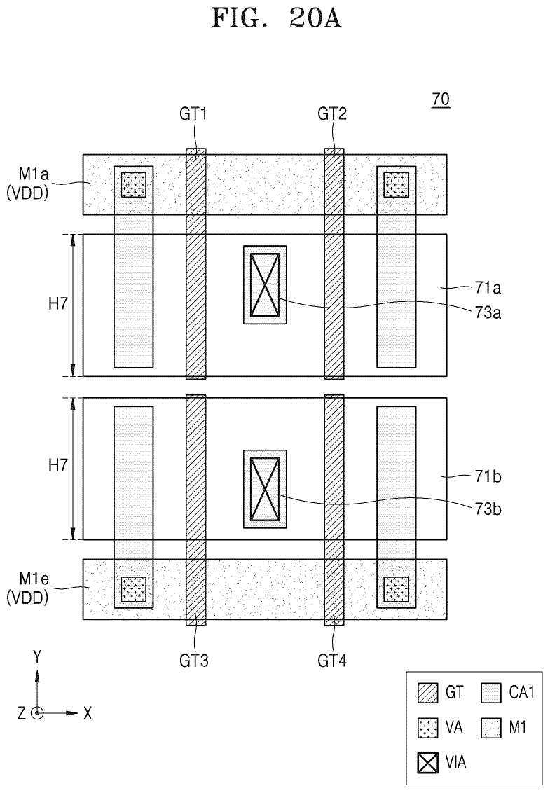

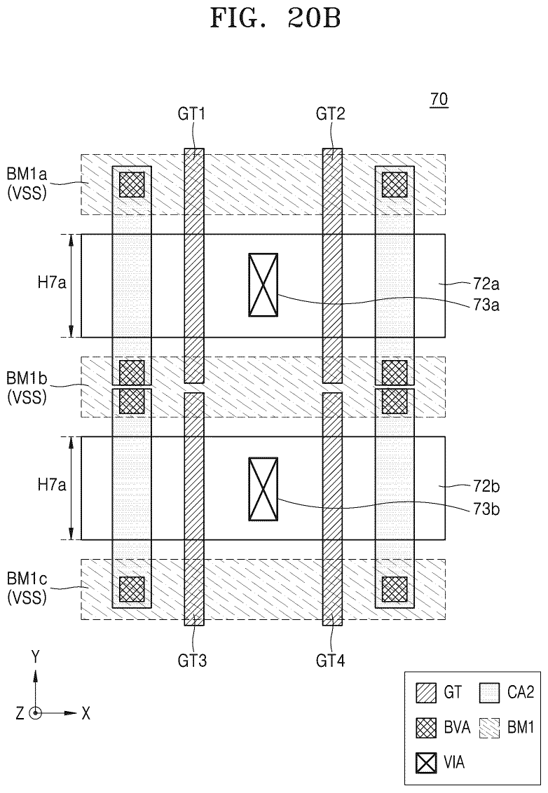

FIGS. 20A and 20B show layouts of an integrated circuit 70 according to an embodiment. At this time, FIG. 20A corresponds to the layout of an upper transistor of a CFET included in the integrated circuit 70, and FIG. 20B corresponds to the layout of a lower transistor of the CFET included in the integrated circuit 70.

Referring to FIG. 20A, the integrated circuit 70 may include first active regions 71a and 71b, the gate lines GT1 to GT4, the first contacts CA1, the frontside vias VA, the frontside wiring layer M1, and via structures 73a and 73b. The first active regions 71a and 71b may each extend in the first direction X and be spaced apart from each other in the second direction Y. Gate lines GT1 and GT3 may be arranged in a row in the second direction Y, and gate lines GT2 and GT4 may be arranged in a row in the second direction Y. At this time, the first active regions 71a and 71b may each have a seventh height H7 in the second direction Y. The frontside wiring layer M1 may include frontside power rails M1a and M1e, each extending in the first direction X. At this time, the integrated circuit 70 may include multi-height cells.

Referring to FIG. 20B, the integrated circuit 70 may include second active regions 72a and 72b, the gate lines GT1 to GT4, the second contacts CA2, the backside vias BVA, the backside wiring layer BM1, and the via structures 73a and 73b. The second active regions 72a and 72b may each extend in the first direction X and be spaced apart from each other in the second direction Y. The gate lines GT1 and GT3 may be arranged in a row in the second direction Y, and the gate lines GT2 and GT4 may be arranged in a row in the second direction Y. At this time, the second active regions 72a and 72b may each have a seventh height H7a in the second direction Y. The backside wiring layer BM1 may include the backside power rails BM1a, BM1b, and BM1c each extending in the first direction X. According to embodiments, a lower transistor of a CFET may be connected to backside power rails through a DBC of the CFET, and the present embodiment may be modified according to the embodiment shown in FIGS. 8 and 9.

According to an embodiment, the frontside power rails M1a and M1e may receive the power voltage VDD, and the first active regions 71a and 71b, the first contacts CA1, and the gate lines GT1 to GT4 may constitute a PFET included in a CFET. Also, the backside power rails BM1a, BM1b, and BM1c may receive the ground voltage VSS, and the second active regions 72a and 72b, the second contacts CA2, and the gate lines GT1 to GT4 may constitute an NFET included in the CFET.

However, the disclosure is not limited thereto. According to one or more embodiments, the frontside power rails M1a and M1e may receive the ground voltage VSS, and the first active regions 71a and 71b, the first contacts CA1, and the gate lines GT1 to GT4 may constitute an NFET included in the CFET. Also, the backside power rails BM1a, BM1b, and BM1c may receive the power voltage VDD, and the second active regions 72a and 72b, the second contacts CA2, and the gate lines GT1 to GT4 may constitute a PFET included in the CFET.

The gate lines GT1 to GT4 may each extend in the vertical direction Z, and thus the upper transistor and the lower transistor of the integrated circuit 70 may share the gate lines GT1 to GT4. The via structures 73a and 73b may each extend in the vertical direction Z, and thus source/drain regions of the first active regions 71a and 71b may be electrically connected to source/drain regions of the second active regions 72a and 72b. According to an embodiment, the backside power rail BM1a may be at least partially overlapped by the frontside power rail M1a in the vertical direction Z, and a backside power rail BM1c may be at least partially overlapped by a frontside power rail M1e in the vertical direction Z.

According to an embodiment, the seventh height H7 of each of the first active regions 71a and 71b may be greater than the seventh height H7a of each of the second active regions 72a and 72b. Therefore, an upper transistor (e.g., a PFET) of a CFET may be implemented as a high-performance transistor, and a lower transistor (e.g., an NFET) of the CFET may be implemented as a high-speed transistor.

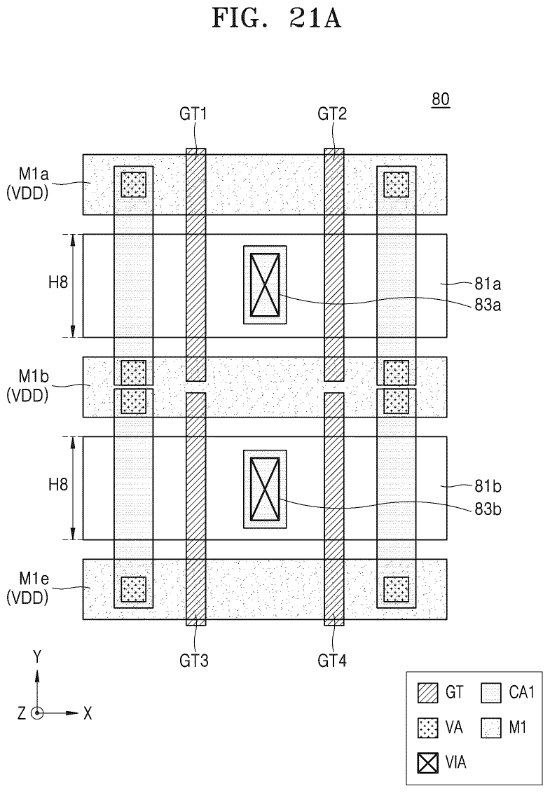

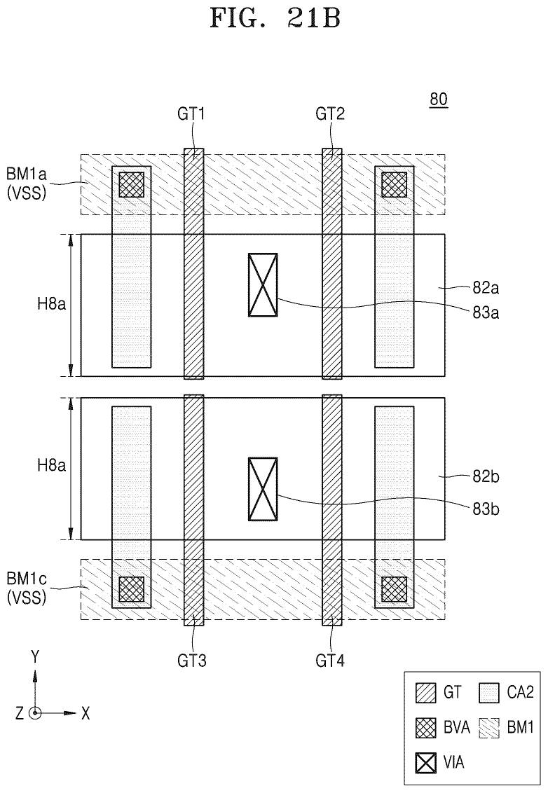

FIGS. 21A and 21B show layouts of an integrated circuit 80 according to an embodiment. At this time, FIG. 21A corresponds to the layout of an upper transistor of a CFET included in the integrated circuit 80, and FIG. 21B corresponds to the layout of a lower transistor of the CFET included in the integrated circuit 80.

Referring to FIG. 21A, the integrated circuit 80 may include first active regions 81a and 81b, the gate lines GT1 to GT4, the first contacts CA1, the frontside vias VA, the frontside wiring layer M1, and via structures 83a and 83b. The first active regions 81a and 81b may each extend in the first direction X and be spaced apart from each other in the second direction Y. The gate lines GT1 and GT3 may be arranged in a row in the second direction Y, and the gate lines GT2 and GT4 may be arranged in a row in the second direction Y. At this time, the first active regions 81a and 81b may each have an eighth height H8 in the second direction Y. The frontside wiring layer M1 may include the frontside power rails M1a, M1b, and M1e, each extending in the first direction X. At this time, the integrated circuit 80 may include multi-height cells.

Referring to FIG. 21B, the integrated circuit 80 may include second active regions 82a and 82b, the gate lines GT1 to GT4, the second contacts CA2, the backside vias BVA, the backside wiring layer BM1, and the via structures 83a and 83b. The second active regions 82a and 82b may each extend in the first direction X and be spaced apart from each other in the second direction Y. The gate lines GT1 and GT3 may be arranged in a row in the second direction Y, and the gate lines GT2 and GT4 may be arranged in a row in the second direction Y. At this time, the second active regions 82a and 82b may each have an eighth height H8a in the second direction Y. The backside wiring layer BM1 may include backside power rails BM1a and BM1c, each extending in the first direction X. According to embodiments, a lower transistor of a CFET may be connected to backside power rails through a DBC of the CFET, and the present embodiment may be modified according to the embodiment shown in FIGS. 8 and 9.

According to an embodiment, the frontside power rails M1a, M1b, and M1e may receive the power voltage VDD, and the first active regions 81a and 81b, the first contacts CA1, and the gate lines GT1 to GT4 may constitute a PFET included in a CFET. Also, the backside power rails BM1a and BM1c may receive the ground voltage VSS, and the second active regions 82a and 82b, the second contacts CA2, and the gate lines GT1 to GT4 may constitute an NFET included in the CFET.

However, the disclosure is not limited thereto. According to one or more embodiments, the frontside power rails M1a, M1b, and M1e may receive the ground voltage VSS, and the first active regions 81a and 81b, the first contacts CA1, and the gate lines GT1 to GT4 may constitute an NFET included in the CFET. Also, the backside power rails BM1a and BM1c may receive the power voltage VDD, and the second active regions 82a and 82b, the second contacts CA2, and the gate lines GT1 to GT4 may constitute a PFET included in the CFET.

The gate lines GT1 to GT4 may each extend in the vertical direction Z, and thus the upper transistor and the lower transistor of the integrated circuit 80 may share the gate lines GT1 to GT4. The via structures 83a and 83b may each extend in the vertical direction Z, and thus source/drain regions of the first active regions 81a and 81b may be electrically connected to source/drain regions of the second active regions 82a and 82b. According to an embodiment, the backside power rail BM1a may be at least partially overlapped by the frontside power rail M1a in the vertical direction Z, and a backside power rail BM1c may be at least partially overlapped by a frontside power rail M1e in the vertical direction Z.

According to an embodiment, the eighth height H8a of each of the second active regions 82a and 82b may be greater than the eighth height H8 of each of the first active regions 81a and 81b. Therefore, an upper transistor (e.g., a PFET) of a CFET may be implemented as a high-speed transistor, and a lower transistor (e.g., an NFET) of the CFET may be implemented as a high-performance transistor.

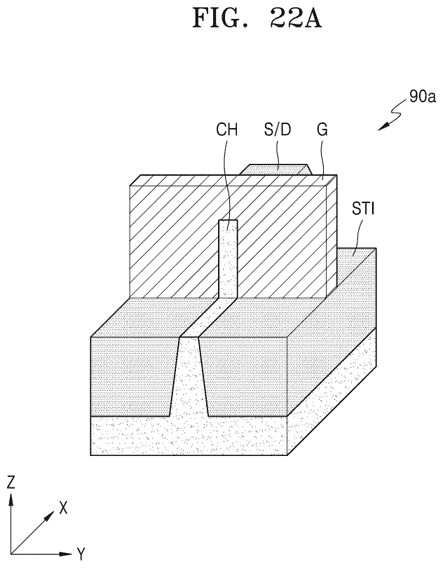

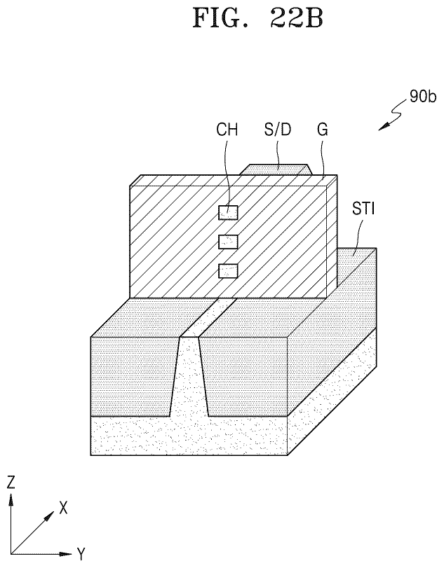

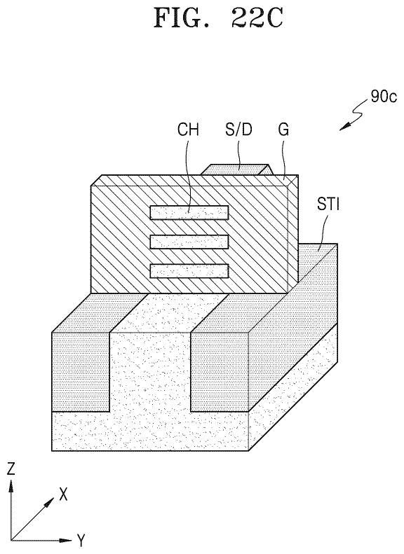

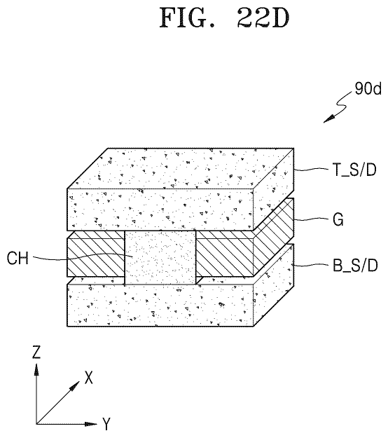

FIGS. 22A to 22D show devices according to one or more embodiments of the disclosure, respectively. For example, each of a first transistor or an upper transistor and/or a second transistor or a lower transistor included in a CFET may be implemented in the structure shown in FIGS. 22A to 22D.

For example, FIG. 22a shows a FinFET 90a, FIG. 22b shows a gate-all-around field effect transistor (GAAFET) 90b, FIG. 22c shows a multi-bridge channel field effect transistor (MBCFET) 90c, and FIG. 22d shows a vertical field effect transistor (VFET) 90d. For convenience of illustration, FIGS. 22A to 22C show structures in which one of two source/drain regions is removed, and FIG. 22D shows a cross-section of the VFET 90d cut along the plane parallel to the plane consisting of the second direction Y and the vertical direction Z and passing through a channel CH of the VFET 90d.

Referring to FIG. 22A, the FinFET 90a may formed by a fin-type active pattern extending in the first direction X between STIs and a gate G extending in the second direction Y. A source/drain S/D may be formed on both sides of the gate G, and thus a source and a drain may be spaced apart from each other in the Y-axis direction. An insulation layer may be formed between the channel CH and the gate G. According to one or more embodiments, FinFET 90a may be formed by a plurality of active patterns spaced apart from each other in the second direction Y and the gate G.

Referring to FIG. 22B, the GAAFET 90b may be formed by active patterns (i.e., nanowires) extending in the first direction X and spaced apart from each other in the Z-axis direction and the gate G extending in the second direction Y. A source/drain S/D may be formed on both sides of the gate G, and thus a source and a drain may be spaced apart from each other in the Y-axis direction. An insulation layer may be formed between the channel CH and the gate G. The number of nanowires included in GAAFET 90b is not limited to that shown in FIG. 22B.

Referring to FIG. 22C, the MBCFET 90c may be formed by active patterns (i.e., nano-sheets) extending in the first direction X and spaced apart from each other in the vertical direction Z and the gate G extending in the second direction Y. A source/drain S/D may be formed on both sides of the gate G, and thus a source and a drain may be spaced apart from each other in the Y-axis direction. An insulation layer may be formed between the channel CH and the gate G. The number of nanosheets included in the MBCFET 90c is not limited to that shown in FIG. 22C.

Referring to FIG. 22D, the VFET 90d may include a top source/drain T_S/D and a bottom source/drain B_S/D spaced apart from each other in the vertical direction Z with the channel CH therebetween. The VFET 90d may include the gate electrode G surrounding the circumference of the channel CH between the top source/drain T_S/D and the bottom source/drain B_S/D. An insulation layer may be formed between the channel CH and the gate G.

However, transistors according to embodiments are not limited to the above-stated structure. For example, an integrated circuit may include a ForkFET in which nano-sheets for a P-type transistor and nano-sheets for an N-type transistor are separated from each other by a dielectric wall, and thus an N-type transistor and a P-type transistor have structures closer to each other. Also, an integrated circuit may include bipolar junction transistors as well as FETs such as CFETs, NCFETs, CNT FETs, etc.

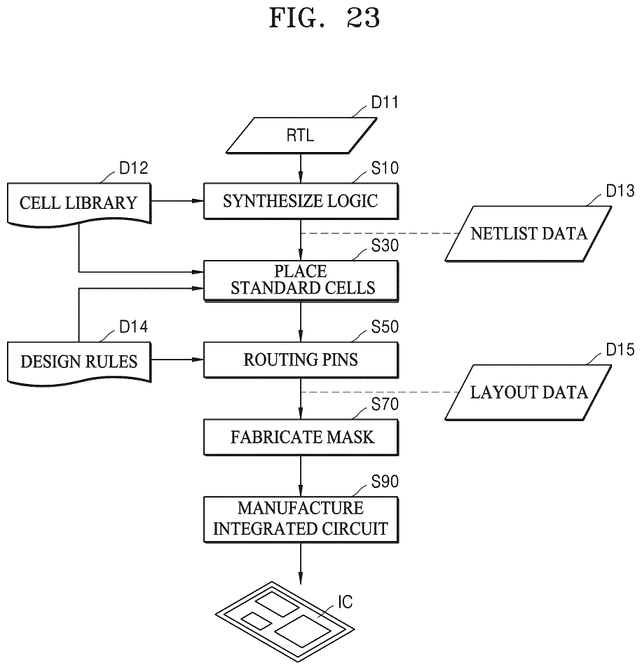

FIG. 23 is a flowchart of a method of manufacturing an integrated circuit, according to an embodiment.

Referring to FIG. 23, the method according to the present embodiment is a method of manufacturing an integrated circuit IC including standard cells and may include a plurality of operations S10, S30, S50, S70, and S90. A cell library (or a standard cell library) D12 may include information regarding standard cells, e.g., function information, characteristic information, layout information, etc. According to one or more embodiments, the cell library D12 may define tap cells and dummy cells as well as functional cells that generate an output signal from an input signal. According to one or more embodiments, the cell library D12 may define memory cells and dummy cells having the same footprint, that is, the same length in the X-axis direction and the Y-axis direction. Design rules D14 may include conditions that the layout of the integrated circuit IC need to comply with. For example, the design rules D14 may include conditions regarding spaces between patterns, the minimum width of the patterns, a routing direction of a wiring layer, etc. in the same layer. In one or more embodiments, the design rules D14 may define the minimum separation distance within the same track of a wiring layer.

In operation S10, a logical synthesis operation for generating netlist data D13 from RTL data D11 may be performed. For example, a semiconductor design tool (e.g., a logical synthesis tool) may perform a logical synthesis with reference to the cell library D12 from the RTL data D11 composed in a VHSIC Hardware Description Language (VHDL) and a Verilog and generate the netlist data D13 including a bitstream or a netlist. The netlist data D13 may correspond to input of place and routing, which will be described later.

In operation S30, standard cells may be arranged. For example, a semiconductor design tool (e.g., a P&R tool) may arrange (or place) standard cells used in the netlist data D13 with reference to the cell library D12. According to one or more embodiments, a semiconductor design tool may place standard cells in a row extending in an X-axis direction or a Y-axis direction, and placed standard cells may receive power from power rails extending along boundaries of the row.

In operation S50, pins of standard cells may be routed. For example, the semiconductor design tool may generate interconnections electrically connecting output pins and input pins of arranged standard cells and generate layout data D15 defining the arranged standard cells and the interconnections. An interconnection may include vias of a via layer and/or patterns of wiring layers. The wiring layers may include a frontside wiring layer disposed above the front side of the substrate and a backside wiring layer disposed on the back side of the substrate. The layout data D15 may have a format like GDSII and may include geometric information regarding cells and interconnections. The semiconductor design tool may refer to the design rules D14 while routing pins of cells. The layout data D15 may correspond to the output of place and routing. Operation S50 may alone be referred to as a method of designing an integrated circuit or operations S30 and S50 may collectively be referred to as a method for designing an integrated circuit.

As shown in FIGS. 1 to 21B, an integrated circuit may implement a CFET by utilizing a frontside power rail and a backside power rail to which different supply voltages are applied, thereby reducing the implementation area of the CFET. Also, a CFET may receive supply voltages from a plurality of frontside power rails and a plurality of backside power rails, thereby improving the operation speed of the CFET. Therefore, the performance of an integrated circuit may be improved. Furthermore, by increasing an active region of a CFET, the driving strength of the CFET may be increased, thereby further improving the performance of an integrated circuit.

Also, according to the disclosure, an integrated circuit may reduce the routing complexity of a frontside wiring layer and improve the PPA of the integrated circuit by using a backside wiring layer as a power rail. Furthermore, the PPA of an integrated circuit may be further improved by having a DBC structure that directly connects a source/drain region to a power rail of a backside wiring layer.

In operation S70, an operation for fabricating a mask may be performed. For example, optical proximity correction (OPC) for correcting distortions due to characteristics of light (e.g., refraction) in photolithography may be applied to the layout data D15. Patterns on the mask may be defined to form patterns to be arranged in a plurality of layers based on OPC-applied data, and at least one mask (or photomask) for forming patterns of each of the layers may be manufactured. In one or more embodiments, the layout of the IC may be limitedly modified in operation S70, and the limited modification of the IC in operation S70 is a post-processing for optimizing the structure of the IC and may be referred to as design polishing.

In operation S90, an operation for manufacturing the integrated circuit IC may be performed. For example, the integrated circuit IC may be manufactured by patterning the plurality of layers by using the at least one mask fabricated in operation S70. A front-end-of-line (FEOL) may include, for example, planarizing and cleaning the wafer, forming a trench, forming a well, forming a gate line, and forming a source and a drain. Individual devices such as a transistor, a capacitor, and a resistor may be formed on a substrate through the FEOL. Also, for example, a back-end-of-line (BEOL) may include operations like silicidation of a gate, a source region, and a drain region, adding a dielectric, planarizing, forming holes, adding metal layers, forming vias, and forming a passivation layer. Individual devices such as a transistor, a capacitor, and a resistor may be connected to one another through the BEOL. In one or more embodiments, a middle-of line (MOL) may be performed between the FEOL and the BEOL, and contacts may be formed on individual elements. Next, the integrated circuit IC may be packaged in a semiconductor package and used as a component for various applications.

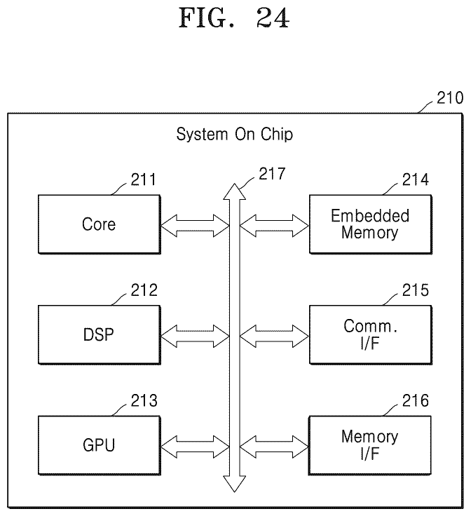

FIG. 24 is a block diagram showing a system-on-chip (SoC) 210 according to an embodiment.

Referring to FIG. 24, the SoC 210 may refer to an integrated circuit on which parts of a computing system or other electronic systems are integrated. For example, as an example of the SoC 210, an application processor (AP) may include a processor and parts for other functions. The SoC 210 may include a core 211, a digital signal processor (DSP) 212, a graphics processing unit (GPU) 213, an embedded memory 214, a communication interface 215, and a memory interface 216. The components of the SoC 210 may communicate with one another through a bus 217.

The core 211 may process instructions and control operations of the components included in the SoC 210. For example, the core 211 may process a series of instructions, thereby driving an operating system and executing applications on the operating system. The DSP 212 may generate useful data by processing digital signals, e.g., digital signals provided from the communication interface 215. The GPU 213 may generate data for images output through a display device from image data provided from the embedded memory 214 or the memory interface 216 or encode image data. According to one or more embodiments, the integrated circuit described above with reference to the attached drawings may be included in the core 211, the DSP 212, the GPU 213, and/or the embedded memory 214.

The embedded memory 214 may store data needed for operations of the core 211, the DSP 212, and the GPU 213. The communication interface 215 may provide an interface for a communication network or one-to-one communication. The memory interface 216 may provide an interface for an external memory of the SoC 210, e.g., a dynamic random access memory (DRAM), a flash memory, etc.

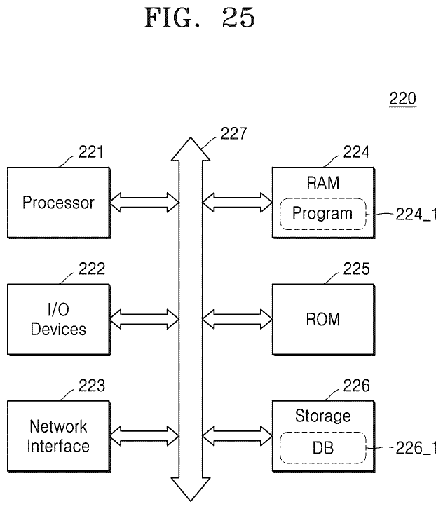

FIG. 25 is a block diagram showing a computing system 220 including a memory storing a program, according to an embodiment.

Referring to FIG. 25, at least some of operations included in a method of designing an integrated circuit according to embodiments (e.g., operations of the above-stated flowchart) may be performed by the computing system (or a computer) 220. The computing system 220 may include a processor 221, input/output devices 222, a network interface 223, a random access memory (RAM) 224, a read only memory (ROM) 225, and a storage device 226. The processor 221, the input/output devices 222, the network interface 223, the RAM 224, the ROM 225, and the storage device 226 may be connected to a bus 227 and may communicate with one another through the bus 227.

The processor 221 may be referred to as a processing unit and, for example, may include at least one core, e.g., a micro-processor, an application processor (AP), a digital signal processor (DSP), a graphics processing unit (GPU), etc., capable of executing an arbitrary instruction set (e.g., Intel Architecture-32 (IA-32), 64-bit extended IA-32, x86-64, PowerPC, Sparc, MIPS, ARM, IA-64, etc.). For example, the processor 221 may access a memory, that is, the RAM 224 or the ROM 225, through the bus 227 and may execute instructions stored in the RAM 224 or the ROM 225.

The RAM 224 may store a program 224_1 for a method of designing an integrated circuit according to an embodiment or at least a portion of the program 224_1, and the program 224_1 may instruct the processor 221 to perform at least some of operations included in the methods of designing an integrated circuit, e.g., the method of FIG. 23. In other words, the program 224_1 may include a plurality of instructions that may be executed by the processor 221, and the instructions included in the program 224_1 may instruct the processor 221 to perform at least some of operations included in the above-stated flowcharts, for example.

The storage device 226 may not lose stored data even when power supplied to the computing system 220 is cut off. The storage device 226 may store the program 224_1 according to an embodiment, and, before the program 224_1 is executed by the processor 221, the program 224_1 or at least a part thereof may be loaded to the RAM 224. Alternatively, the storage device 226 may store a file written in a program language, and the program 224_1 generated from the file by a compiler or the like or at least a part of the program 224_1 may be loaded to the RAM 224. Also, the storage device 226 may store a database 226_1, and the database 226_1 may store information necessary for designing an integrated circuit, such as information regarding designed blocks, the cell library D12 and/or the design rules D14 of FIG. 23, etc.

The storage device 226 may store data to be processed by the processor 221 or data processed by the processor 221. In other words, the processor 221 may generate data by processing data stored in the storage device 226 according to the program 224_1 and may store generated data in the storage device 226. For example, the storage device 226 may store the RTL data D11, the netlist data D13, and/or the layout data D15 of FIG. 23.

The input/output devices 222 may include an input device like a keyboard and a pointing device and may include an output device like a display device and a printer. For example, through the input/output devices 222, a user may trigger execution of the program 224_1 through the processor 221, input the RTL data D11 and/or the netlist data D13 of FIG. 23, or check the layout data D15 of FIG. 23. The network interface 223 may provide access to a network outside the computing system 220. For example, a network may include a plurality of computing systems and communication links, and the communication links may include wired links, optical links, wireless links, or any other types of links.

While the disclosure has been particularly shown and described with reference to embodiments thereof, it will be understood that various changes in form and details may be made therein without departing from the spirit and scope of the following claims.

What is claimed is:

1. An integrated circuit comprising:
a complementary field effect transistor comprising a first transistor and a second transistor arranged in a vertical direction on a front side of a substrate;
a via structure extending in the vertical direction on the second transistor and connecting the second transistor to the first transistor;
at least one frontside power rail above the first transistor in the vertical direction and configured to transmit a first supply voltage to the first transistor;
a backside via penetrating through the substrate in the vertical direction; and
at least one backside power rail on a back side of the substrate and configured to transmit a second supply voltage to the second transistor through the backside via,
wherein the first supply voltage and the second supply voltage are different, and
wherein the first transistor and the second transistor share a gate line.

2. The integrated circuit of claim 1,
wherein the at least one backside power rail comprises a first backside power rail and a second backside power rail, each below the complementary field effect transistor in the vertical direction and extending in a first direction,
wherein the at least one frontside power rail comprises a first frontside power rail and a second frontside power rail, each above the complementary field effect transistor in the vertical direction and extending in the first direction,
wherein the first transistor is configured to receive the first supply voltage from the first frontside power rail and the second frontside power rail, and
wherein the second transistor is configured to receive the second supply voltage from the first backside power rail and the second backside power rail.

3. The integrated circuit of claim 2,
wherein the first transistor is in a first active region of the integrated circuit and extends in the first direction,
wherein the second transistor is disposed in a second active region of the integrated circuit and extends in the first direction, and
wherein the first active region does not overlap the first frontside power rail and the second frontside power rail, and the second active region does not overlap the first backside power rail and the second backside power rail.

4. The integrated circuit of claim 2,
wherein the first frontside power rail and the first backside power rail at least partially overlap each other in the vertical direction, and
wherein the second frontside power rail and the second backside power rail at least partially overlap each other in the vertical direction.

5. The integrated circuit of claim 1,
wherein the at least one backside power rail comprises a first backside power rail below the complementary field effect transistor in the vertical direction and extending in a first direction,
wherein the at least one frontside power rail comprises a first frontside power rail above the complementary field effect transistor in the vertical direction and extending in the first direction,
wherein the first transistor is configured to receive the first supply voltage from the first frontside power rail, and
wherein the second transistor is configured to receive the second supply voltage from the first backside power rail.

6. The integrated circuit of claim 5,
wherein the first transistor is in a first active region of the integrated circuit extending in the first direction,
wherein the second transistor is in a second active region of the integrated circuit extending in the first direction,
wherein the first active region at least partially overlaps the first backside power rail, and
wherein the second active region at least partially overlaps the first frontside power rail.

7. The integrated circuit of claim 5, wherein the first frontside power rail and the first backside power rail do not overlap each other in the vertical direction.

8. The integrated circuit of claim 5, wherein the first frontside power rail and the first backside power rail at least partially overlap each other in the vertical direction.

9. The integrated circuit of claim 1,
wherein the first transistor comprises a P-type transistor, and the second transistor comprises an N-type transistor,
wherein the first supply voltage is a positive supply voltage, and the second supply voltage is a negative supply voltage,
wherein the at least one frontside power rail is configured to transmit the positive supply voltage to a source of the P-type transistor, and
wherein the at least one backside power rail is configured to transmit the negative supply voltage to a source of the N-type transistor.

10. The integrated circuit of claim 1,
wherein the first transistor comprises an N-type transistor, and the second transistor comprises a P-type transistor,
wherein the first supply voltage is a negative supply voltage, and the second supply voltage is a positive supply voltage,
wherein the at least one frontside power rail is configured to transmit the negative supply voltage to a source of the N-type transistor, and
wherein the at least one backside power rail is configured to transmit the positive supply voltage to a source of the P-type transistor.

11. The integrated circuit of claim 1, wherein the gate line extends in the vertical direction and is connected to the first transistor and the second transistor.

12. The integrated circuit of claim 1,
wherein the first transistor is in a first active region of the integrated circuit, and the second transistor is disposed in a second active region of the integrated circuit, and
wherein the gate line surrounds the first active region and the second active region.

13. The integrated circuit of claim 12, further comprising a first contact on the first active region,
wherein the via structure connects the second transistor to the first contact.

14. An integrated circuit comprising:
a first active region and a second active region arranged, in a vertical direction with respect to a substrate, on a front side of the substrate;
a gate line extending in the vertical direction and connected to the first active region and the second active region;
a via structure extending in the vertical direction on the second active region and connecting the first active region to the second active region;
a frontside power rail above the first active region in the vertical direction and configured to transmit a first supply voltage to the first active region;
a backside power rail on a back side of the substrate and configured to transmit a second supply voltage to a source/drain region of the second active region; and
a direct backside contact extending in the vertical direction on the backside power rail and connecting the backside power rail to the source/drain region of the second active region,
wherein the first supply voltage and the second supply voltage are different.

15. The integrated circuit of claim 14,
wherein the first supply voltage is a positive supply voltage, and the second supply voltage is a negative supply voltage,
wherein the frontside power rail is configured to transmit the positive supply voltage to a source/drain region of the first active region, and
wherein the backside power rail is configured to transmit the negative supply voltage to the source/drain region of the second active region.

16. The integrated circuit of claim 14,
wherein the first supply voltage is a negative supply voltage, and the second supply voltage is a positive supply voltage,
wherein the frontside power rail is configured to transmit the negative supply voltage to a source/drain region of the first active region, and
wherein the backside power rail is configured to transmit the positive supply voltage to the source/drain region of the second active region.

17. The integrated circuit of claim 14, wherein the frontside power rail and the backside power rail do not overlap each other in the vertical direction.

18. An integrated circuit comprising:
a plurality of first active regions on a front side of a substrate, wherein each first active region of the plurality of first active regions extends in a first direction, is spaced apart from other first active regions of the plurality of first active regions in a second direction intersecting with the first direction, and has a first height in the second direction;
a second active region overlapping the plurality of first active regions in a vertical direction with respect to the substrate and having a second height greater than the first height in the second direction;
a gate line extending in the vertical direction and connected to the plurality of first active regions and the second active region;
a plurality of via structures each extending in the vertical direction on the first active regions and connecting the plurality of first active regions to the second active region;
at least one frontside power rail above the plurality of first active regions and the second active region in the vertical direction and configured to receive a first supply voltage; and
at least one backside power rail on a back side of the substrate and configured to receive a second supply voltage,
wherein the first supply voltage and the second supply voltage are different.

19. The integrated circuit of claim 18,
wherein the plurality of first active regions are arranged above the second active region in the vertical direction,
wherein the at least one frontside power rail is configured to transmit the first supply voltage to source/drain regions of the plurality of first active regions, and
wherein the at least one backside power rail is configured to transmit the second supply voltage to a source/drain region of the second active region.

20. The integrated circuit of claim 19,
wherein the second active region is above the plurality of first active regions in the vertical direction,
wherein the at least one frontside power rail is configured to transmit the first supply voltage to the source/drain region of the second active region, and
wherein the at least one backside power rail is configured to transmit the second supply voltage to the source/drain regions of the plurality of first active regions.
